(19) United States
(12) Patent Application Publication
(10) Pub. No.: US 2008/0087912 A1
(43) Pub. Date: Apr. 17, 2008

(54) Semiconductor device and method for fabricating the same

(76) Inventor: Saichirou Kaneko, Kyoto (JP)

Correspondence Address: MCDERMOTT WILL & EMERY LLP, 600 13TH STREET, NW, WASHINGTON, DC, 20005-3096, US

(21) Appl. No.: 11/878,694

(22) Filed: Jul. 26, 2007

(30) Foreign Application Priority Data
Oct. 17, 2006 (JP) 2006-282440
Apr. 19, 2007 (JP) 2007-110782

(51) Int. Cl. H01L 29/74; H01L 21/332

(52) U.S. Cl. 257/141; 438/135; 257/E29.211; 257/E21.388

(57) ABSTRACT

A resurf region of a second conductivity type and a base region of a first conductivity type adjacent to each other are formed in surface portions of a semiconductor substrate of the first conductivity type. An emitter region of the second conductivity type is formed in the base region to be spaced from the resurf region. A gate insulating film is formed to cover a portion of the base region disposed between the emitter region and the resurf region, and a gate electrode is formed on the gate insulating film. A top semiconductor layer of the first conductivity type electrically connected to the base region is formed in a surface portion of the resurf region. A collector region of the first conductivity type is formed in a surface portion of the resurf region to be spaced from the top semiconductor layer. The collector region and the top semiconductor layer have substantially the same impurity concentration and are disposed at substantially the same depth.

### BACKGROUND OF THE INVENTION

The present invention relates to a semiconductor device and a method for fabricating the same, and more particularly, it relates to a semiconductor device such as a high-breakdown voltage lateral insulating gate type bipolar transistor for use in a switched mode power supply apparatus and a method for fabricating the same.

Recently, it is regarded significant to reduce the standby power of electric home appliances from the viewpoint of preventing the global warming, and there are increasing demands for a switched mode power supply apparatus consuming smaller power in a standby mode.

Now, a conventional switched mode power supply apparatus will be described.

FIG. 36 shows an exemplified circuit configuration of the conventional switched mode power supply apparatus. As shown in FIG. 36, the conventional switched mode power supply apparatus includes a primary rectifying/smoothing circuit 411, a main circuit 412, a transformer 404 and a secondary rectifying/smoothing circuit 421.

Specifically, an AC voltage input between input terminals 416 and 417 of the primary rectifying/smoothing circuit 411 is rectified and smoothed by the primary rectifying/smoothing circuit 411 so as to be supplied to the main circuit 412 as an input DC voltage. At this point, the primary rectifying/smoothing circuit 411 includes a diode bridge 431 and an input capacitor 432, so that a voltage having been full-wave rectified by the diode bridge 431 can be smoothed by the input capacitor 432 for supplying the resultant voltage to the main circuit 412.

The main circuit 412 includes a semiconductor switching device 413 and a voltage control circuit 414. The semiconductor switching device 413 and the voltage control circuit 414 can be integrated on one chip. The transformer 404 includes a primary winding 441, and the primary winding 441 and the semiconductor switching device 413 are serially connected to each other, and the input DC voltage is supplied from the primary rectifying/smoothing circuit 411 to this serially connected circuit.

The control terminal of the semiconductor switching device 413 is connected to the voltage control circuit 414, so that the semiconductor switching device 413 can be controlled to be turned on/off in accordance with a gate signal output by the voltage control circuit 414.

The transformer 404 further includes a secondary winding 442 magnetically coupled to the primary winding 441 and an auxiliary winding 443 magnetically coupled to the primary winding 441 and the secondary winding 442. When the semiconductor switching device 413 is switched and a current intermittently passes through the primary winding 441, a voltage is induced in the secondary winding 442 and the auxiliary winding 443.

The second rectifying/smoothing circuit 421 generates a DC output voltage by rectifying and smoothing the voltage induced in the secondary winding 442 and outputs the DC output voltage from output terminals 426 and 427. Specifically, the secondary rectifying/smoothing circuit 421 includes a diode 422, a choke coil 423 and first and second output capacitors 424 and 425. The choke coil 423 and the first and second output capacitors 424 and 425 are connected to one another in a π shape, and the voltage induced in the secondary winding 442 is half-wave rectified by the diode 422 and is smoothed by the choke coil 423 and the first and second output capacitors 424 and 425.

A voltage generated on the both ends of the auxiliary winding 443 is input to the control terminal of the semiconductor switching device 413 through the voltage control circuit 414. In other words, the switched mode power supply apparatus of FIG. 36 employs a ringing choke converter (RCC) system, and the semiconductor switching device 413 performs a switching operation in a self-excited manner by using the voltage generated in the auxiliary winding 443.

A voltage between the output terminals 426 and 427 is fed back to the voltage control circuit 414 through a photo coupler 429. For example, in the case where the voltage between the output terminals 426 and 427 is lowered, the voltage control circuit 414 forcedly increases an on period of the semiconductor switching device 413, and on the contrary, in the case where the voltage between the output terminals 426 and 427 is increased, the voltage control circuit 414 forcedly reduces an on period of the semiconductor switching device 413. Thus, the voltage appearing between the output terminals 426 and 427 is kept at a given value.

Within the voltage control circuit 414, an auxiliary DC voltage is generated by using the voltage induced in the auxiliary winding 443, and therefore, the voltage control circuit 414 is operated by the auxiliary DC voltage except for the starting time of the switched mode power supply apparatus.

In the starting time of the switched mode power supply apparatus, namely, when the AC voltage is applied between the input terminals 416 and 417, the semiconductor switching device 413 is not in a switching operation, and hence, no voltage is induced in the auxiliary winding 443 and no power is supplied to the voltage control circuit 414. Accordingly, in order to start the switching operation of the semiconductor switching device 413, a low voltage sufficient for activating the voltage control circuit 414 is supplied from the primary rectifying/smoothing circuit 411 through an externally provided resistance 451 (with a high breakdown voltage and high power).

In the aforementioned switched mode power supply apparatus, loss is mainly caused in the semiconductor switching device 413. Generally, a MOSFET (metal oxide semiconductor field effect transistor) is used as the switching device 413. In general, switching loss caused in turning off is large in a bipolar transistor but the switching loss is small in a MOSFET because its switching speed is high. In contrast, a MOSFET has large conducting resistance differently from a bipolar transistor and hence its conducting loss cannot be ignored. Accordingly, when a large current passes through a MOSFET, large loss is caused.

Recently, also in the technical field of switched mode power supply apparatuses, an attention is paid to a bipolar type IGBT (insulated gate bipolar transistor) in which a minority carrier is implanted into a drift layer as compared with a unipolar type MOSFET. In the conventional switched mode power supply apparatus of FIG. 36, if an IGBT is used as the switching device 413, although the conducting resistance is smaller because conductivity modulation is caused as in using a bipolar transistor, the switching speed is lowered and the switching loss is increased because a minority carrier is used.

In the switched mode power supply apparatus of the RCC system described above, in the case where a load connected to the output terminals 426 and 427 is heavy, the switching frequency of the switching device 413 is lowered and an on period of the switching device 413 is increased, and as a result, a large current passes through the primary winding 441 so as to keep the voltage between the output terminals 426 and 427 at a given value. On the contrary, when the load is light as in a standby mode, the switching frequency of the switching device 413 is increased and an on period is reduced, and as a result, the current passing through the primary winding 441 is reduced so as to keep the voltage between the output terminals 426 and 427 at a given value.

Accordingly, comprehensively considering both of the switching loss and the conducting loss, when the load is heavy, the frequency is lowered and the current is increased, and therefore, a MOSFET is disadvantageous and an IGBT is advantageous. On the contrary, when the load is light as in a standby mode, the frequency is increased and the current is reduced, and therefore, a MOSFET is advantageous and an IGBT is disadvantageous.

FIG. 37 is a diagram for showing the comparison, in the relationship between load and loss, between a MOSFET (of a lateral type having a drift region with a resurf structure) and an IGBT (of a lateral type) used in a switched mode power supply apparatus. As shown in FIG. 37, when the output is lower (the load is lighter), the switching frequency is increased and hence the loss caused in the IGBT is larger, but when the output is higher (the load is heavier), the switching frequency is lowered and hence the loss caused in the MOSFET is larger.

Patent Document 1: Japanese Laid-Open Patent Publication No. 7-153951

Patent Document 2: Japanese Laid-Open Patent Publication No. 2002-345242

Patent Document 3: Japanese Patent Publication No. 6-52791 (U.S. Pat. No. 5,072,268)

Patent Document 4: Japanese Patent No. 2629437

Patent Document 5: U.S. Pat. No. 4,811,075

Patent Document 6: U.S. Pat. No. 5,313,082

Patent Document 7: Japanese Laid-Open Patent Publication No. 8-213617

Patent Document 8: Japanese Laid-Open Patent Publication No. 2007-115871 (U.S. patent application Ser. No. 11/582,441)

Non-patent Document 1: D. S. Byeon et al., The separated shorted-anode insulated gate bipolar transistor with the suppressed negative differential resistance regime, Microelectronics Journal 30, 1999, pp. 571-575

### SUMMARY OF THE INVENTION

As described above, in the case where a MOSFET is used as the switching device, the conducting loss is large when the load is heavy, and in the case where an IGBT is used as the switching device, the switching loss is large in the standby mode or when the load is light. Accordingly, it is difficult to reduce the loss in the whole region ranging from light load to heavy load in a conventional semiconductor switching device.

Patent Document 1 proposes an architecture where a vertical type IGBT and a vertical type power MOSFET are both provided in one chip of a switching device. In this architecture, however, the current power of the vertical type power MOSFET is too small as compared with the driving power of the vertical type IGBT, and as a result, it is practically difficult to drive the power MOSFET when the load is light. Furthermore, in this architecture, a step should be formed on the back face of a semiconductor substrate, and hence, the fabrication process is difficult.

Also, Patent Document 2 proposes an architecture where an IGBT of a Schottky junction type is used as the switching device. In the IGBT of the Schottky junction type, however, the loss caused when the load is light is larger than that of a power MOSFET, and the loss caused when the load is heavy is larger than that of a conventional IGBT. Therefore, this architecture of Patent Document 2 cannot always reduce the loss.

Moreover, the switching device described in any of Patent Documents 1 and 2 has a vertical structure. Therefore, when such a vertical switching device is used as the semiconductor switching device 413 of, for example, the conventional switched mode power supply apparatus of FIG. 36, there arises another problem that it is difficult to build the voltage control circuit 414 and the semiconductor switching device 413 in one chip.

Furthermore, although not related to proper use of two kinds of transistors of a MOSFET and an IGBT in one device, Non-patent Document 1 and Patent Document 3 propose a lateral type IGBT having a shorted-anode structure as a semiconductor device corresponding to an intermediate between a MOSFET and an IGBT.

FIG. 38 is a cross-sectional view of an example of the lateral type IGBT having the shorted-anode structure disclosed in Patent Document 3. In the structure of FIG. 38, a P⁺-type pocket 514 and an N⁺-type pocket 515 are short-circuited through a drain electrode 513. In this lateral type IGBT having the shorted-anode structure, when a positive voltage is applied to a gate electrode 512 with positive bias applied between the drain electrode 513 and a source electrode 505, a current starts to flow from the N⁺-type pocket 515 to the source electrode 505 through a N⁺-type source region 507 (which corresponds to a MOSFET operation). When the potential of an N-type well region 503 disposed beneath the P⁺-type pocket 514 becomes lower than that of the P⁺-type pocket 514 by approximately 0.6 V, holes are started to be injected from the P⁺-type pocket 514 to the N-type well region 503, and thus, the MOSFET operation is changed to an IGBT operation. Furthermore, when a gate signal is turned off, electrons are discharged from the N-type well region 503 to the N⁺-type pocket 515, and hence, the shorted-anode lateral type IGBT of FIG. 38 is characterized by a high switching speed. Moreover, since this switching device has the lateral structure, when this switching device is used as, for example, the semiconductor switching device 413 of FIG. 36, the voltage control circuit 414 and the semiconductor switching device 413 can be built on one chip.

However, even when the shorted-anode lateral type IGBT of FIG. 38 is used as the switching device, it is difficult to reduce loss in the whole region ranging from light load to heavy load for the following reason: In this switching device, it is difficult to change the MOSFET operation to the IGBT operation unless the length 523 of the P⁺-type pocket 514 is increased, and hence, the MOSFET operation is performed in a region of light load where the IGBT operation is preferably performed, resulting in increasing the loss. On the other hand, when the length 523 of the P⁺-type pocket 514 is increased, it is easy to cause a potential difference between the P⁺-type pocket 514 and the N-type well region 503, and hence, the change to the IGBT operation is easy. In the case where the length 523 of the P⁺-type pocket 514 is increased, however, the unit area of the device becomes large, and as a result, the on resistance of the device is so large both in the MOSFET operation and the IGBT operation that the loss is increased.

Accordingly, even when the shorted-anode lateral type IGBT of FIG. 38 is used in the switched mode power supply apparatus, it is difficult to practically reduce loss in the whole region ranging from light load to heavy load.

In consideration of the aforementioned conventional problems and disadvantages, an object of the invention is providing a high-breakdown voltage semiconductor device in which loss can be reduced in the whole region ranging from light load to heavy load.

In order to achieve the object, the first semiconductor device of this invention includes a resurf region of a second conductivity type formed in a surface portion of a semiconductor substrate of a first conductivity type; a base region of the first conductivity type formed in the semiconductor substrate to be adjacent to the resurf region; an emitter region of the second conductivity type formed in the base region to be spaced from the resurf region; a first gate insulating film formed to cover a portion of the base region disposed between the emitter region and the resurf region; a first gate electrode formed on the first gate insulating film; a top semiconductor layer of the first conductivity type formed in a surface portion of the resurf region and electrically connected to the base region; a collector region of the first conductivity type formed in a surface portion of the resurf region to be spaced from the top semiconductor layer, having substantially the same impurity concentration as the top semiconductor layer and disposed at substantially the same depth as the top semiconductor layer; a collector electrode formed above the semiconductor substrate and electrically connected to the collector region; and an emitter electrode formed above the semiconductor substrate and electrically connected to the base region and the emitter region.

Specifically, the first semiconductor device of this invention is a lateral type IGBT, and since the impurity concentration in the collector region is set to be substantially as low as the impurity concentration in the top semiconductor layer in this IGBT, the amount of excessive carriers injected into the semiconductor substrate during an IGBT operation can be suppressed as compared with the case where the collector region is made of a high concentration layer. As a result, since the amount of excessive carriers remaining in the semiconductor substrate in turn off can be reduced, time necessary for drawing the carriers can be shortened, and hence, the switching speed can be improved, so as to reduce the switching loss. In other words, a high-breakdown voltage semiconductor device in which the loss can be reduced in the whole region ranging from light load to heavy load can be realized.

Furthermore, in the case where the collector region is made of a high concentration layer, it is necessary to provide a buffer layer of the second conductivity with a higher impurity concentration than the resurf region between the collector region and the resurf region for reducing the efficiency for injecting holes from the collector region to the resurf region. On the contrary, since the collector region has a low concentration in the first semiconductor device of this invention, there is no need to provide such a buffer layer of the second conductivity, and hence, the fabrication process can be simplified.

Herein, “substantially the same impurity concentration” means that a concentration difference is approximately 1×10¹/cm³ or less, in other words, it means that concentrations fall within a range of the same order in exponential notation, and “substantially the same depth” means that a depth difference is approximately 1 μm or less.

The second semiconductor device of the invention includes a resurf region of a second conductivity type formed in a surface portion of a semiconductor substrate of a first conductivity type; a base region of the first conductivity type formed in the semiconductor substrate to be adjacent to the resurf region; an emitter/source region of the second conductivity type formed in the base region to be spaced from the resurf region; a first gate insulating film formed to cover a portion of the base region disposed between the emitter/source region and the resurf region; a first gate electrode formed on the first gate insulating film; a top semiconductor layer of the first conductivity type formed in a surface portion of the resurf region and electrically connected to the base region; a collector region of the first conductivity type formed in a surface portion of the resurf region to be spaced from the top semiconductor layer, having substantially the same impurity concentration as the top semiconductor layer and disposed at substantially the same depth as the top semiconductor layer; a drain region of the second conductivity type formed in a surface portion of the resurf region to be spaced from the top semiconductor layer; a collector/drain electrode formed above the semiconductor substrate and electrically connected to the collector region and the drain region; and an emitter/source electrode formed above the semiconductor substrate and electrically connected to the base region and the emitter/source region.

Specifically, the second semiconductor device of the invention is a semiconductor device performing a MOSFET operation or an IGBT operation in accordance with the amount of collector current, and since the impurity concentration in the collector region is set to be substantially as low as the impurity concentration in the top semiconductor layer in this semiconductor device, the amount of excessive carriers injected into the semiconductor substrate during the IGBT operation can be suppressed as compared with the case where the collector region is made of a high concentration layer. As a result, since the amount of excessive carriers remaining in the semiconductor substrate in turn off can be reduced, time necessary for drawing the carriers can be shortened, and hence, the switching speed can be improved, so as to reduce the switching loss. In other words, a high-breakdown voltage semiconductor device in which the loss can be reduced in the whole region ranging from light load to heavy load can be realized.

Furthermore, in the case where the collector region is made of a high concentration layer, it is necessary to provide a buffer layer of the second conductivity with a higher impurity concentration than the resurf region between the collector region and the resurf region for reducing the efficiency for injecting holes from the collector region to the resurf region. On the contrary, since the collector region has a low concentration in the second semiconductor device of this invention, there is no need to provide such a buffer layer of the second conductivity, and hence, the fabrication process can be simplified. Moreover, a problem derived from such a buffer layer of the second conductivity that the MOSFET operation is difficult to change to the IGBT operation can be avoided.

In the second semiconductor device of the invention, each of the collector region and the drain region preferably includes a plurality of sections separated from one another, and the sections of the collector region and the sections of the drain region are preferably alternately arranged along a direction vertical to a direction extending from the collector region toward the emitter/source region.

Thus, a collector voltage Vch at which the MOSFET operation is changed to the IGBT operation in the semiconductor device performing the MOSFET operation or the IGBT operation in accordance with the amount of collector current can be easily controlled by changing the length of each section of the collector region.

The first or second semiconductor device of the invention preferably further includes a second gate insulating film formed on the resurf region to extend from a portion on the collector region to a portion on the top semiconductor layer; and a second gate electrode formed on the second gate insulating film.

Thus, the excessive carriers can be further drawn through the top semiconductor layer by turning on the second gate electrode at the time of turn off, and hence, the time necessary for drawing the carriers can be further shortened, resulting in further improving the switching speed.

In this case, the semiconductor device preferably further includes a buried semiconductor layer of the first conductivity type formed in the resurf region to be in contact with the top semiconductor layer and electrically connected to the base region.

Thus, since the buried semiconductor layer is further formed in the resurf region, the excessive carriers remaining in the resurf region can be efficiently drawn through not only the top semiconductor layer but also the buried semiconductor layer in turn off during the IGBT operation, the time necessary for drawing the carriers can be further shortened, resulting in further improving the switching speed. Moreover, as compared with the case where the top semiconductor layer alone is formed in the resurf region, a depletion layer can be formed from the buried semiconductor layer in both the upward and downward directions, and hence, the impurity concentration in the resurf region can be made much higher, so as to improve the switching speed and reduce the on resistance.

The first method for fabricating a semiconductor device of the invention is a method for fabricating the first or second semiconductor device of this invention and includes at least a step of forming the top semiconductor layer and the collector region through one impurity implantation process.

In the first method for fabricating a semiconductor device, since the top semiconductor layer and the collector region are formed through one and the same impurity implantation process, the number of procedures can be reduced as compared with the case where the top semiconductor layer and the collector regions are individually formed, and hence, the cost can be reduced.

The third semiconductor device of the invention includes a resurf region of a second conductivity type formed in a surface portion of a semiconductor substrate of a first conductivity type; a base region of the first conductivity type formed in the semiconductor substrate to be adjacent to the resurf region; an emitter region of the second conductivity type formed in the base region to be spaced from the resurf region; a gate insulating film formed to cover a portion of the base region disposed between the emitter region and the resurf region; a gate electrode formed on the gate insulating film; a buried semiconductor layer of the first conductivity type formed in the resurf region and electrically connected to the base region; a collector region of the first conductivity type formed in the resurf region to be spaced from the buried semiconductor layer, having substantially the same impurity concentration as the buried semiconductor layer and disposed at substantially the same depth as the buried semiconductor layer; a collector contact region of the first conductivity type formed in a surface portion of the resurf region to be in contact with the collector region; a collector electrode formed above the semiconductor substrate and electrically connected to the collector contact region; and an emitter electrode formed above the semiconductor substrate and electrically connected to the base region and the emitter region.

Specifically, the third semiconductor device of this invention is a lateral type IGBT, and since the impurity concentration in the collector region is set to be substantially as low as the impurity concentration in the top semiconductor layer in this IGBT, the amount of excessive carriers injected into the semiconductor substrate during an IGBT operation can be suppressed as compared with the case where the collector region is made of a high concentration layer. As a result, since the amount of excessive carriers remaining in the semiconductor substrate in turn off can be reduced, time necessary for drawing the carriers can be shortened, and hence, the switching speed can be improved, so as to reduce the switching loss. In other words, a high-breakdown voltage semiconductor device in which the loss can be reduced in the whole region ranging from light load to heavy load can be realized.

Also, since the buried semiconductor layer is formed in the resurf region in the third semiconductor device of the invention, a depletion layer can be formed from the buried semiconductor layer both in the upward and downward directions, and hence, the impurity concentration in the resurf region can be increased, so as to improve the switching speed and reduce the on resistance.

Furthermore, in the case where the collector region is made of a high concentration layer, it is necessary to provide a buffer layer of the second conductivity with a higher impurity concentration than the resurf region between the collector region and the resurf region for reducing the efficiency for injecting holes from the collector region to the resurf region. On the contrary, since the collector region has a low concentration in the third semiconductor device of this invention, there is no need to provide such a buffer layer of the second conductivity, and hence, the fabrication process can be simplified.

The fourth semiconductor device of this invention includes a resurf region of a second conductivity type formed in a surface portion of a semiconductor substrate of a first conductivity type; a base region of the first conductivity type formed in the semiconductor substrate to be adjacent to the resurf region; an emitter/source region of the second conductivity type formed in the base region to be spaced from the resurf region; a gate insulating film formed to cover a portion of the base region disposed between the emitter/source region and the resurf region; a gate electrode formed on the gate insulating film; a buried semiconductor layer of the first conductivity type formed in the resurf region and electrically connected to the base region; a collector region of the first conductivity type formed in the resurf region to be spaced from the buried semiconductor layer, having substantially the same impurity concentration as the buried semiconductor layer and disposed at substantially the same depth as the buried semiconductor layer; a collector contact region of the first conductivity type formed in a surface portion of the resurf region to be in contact with the collector region; a drain region of the second conductivity type formed in a surface portion of the resurf region to be spaced from the buried semiconductor layer; a collector/drain electrode formed above the semiconductor substrate and electrically connected to the collector contact region and the drain region; and an emitter/source electrode formed above the semiconductor substrate and electrically connected to the base region and the emitter/source region.

Specifically, the fourth semiconductor device of this invention is a semiconductor device performing a MOSFET operation or an IGBT operation in accordance with the amount of collector current, and since the impurity concentration in the collector region is set to be substantially as low as the impurity concentration in the top semiconductor layer in this semiconductor device, the amount of excessive carriers injected into the semiconductor substrate during the IGBT operation can be suppressed as compared with the case where the collector region is made of a high concentration layer. As a result, since the amount of excessive carriers remaining in the semiconductor substrate in turn off can be reduced, time necessary for drawing the carriers can be shortened, and hence, the switching speed can be improved, so as to reduce the switching loss. In other words, a high-breakdown voltage semiconductor device in which the loss can be reduced in the whole region ranging from light load to heavy load can be realized.

Also, since the buried semiconductor layer is formed in the resurf region in the fourth semiconductor device of the invention, a depletion layer can be formed from the buried semiconductor layer both in the upward and downward directions, and hence, the impurity concentration in the resurf region can be increased, so as to improve the switching speed and reduce the on resistance.

Furthermore, in the case where the collector region is made of a high concentration layer, it is necessary to provide a buffer layer of the second conductivity with a higher impurity concentration than the resurf region between the collector region and the resurf region for reducing the efficiency for injecting holes from the collector region to the resurf region. On the contrary, since the collector region has a low concentration in the fourth semiconductor device of this invention, there is no need to provide such a buffer layer of the second conductivity, and hence, the fabrication process can be simplified. Moreover, a problem derived from such a buffer layer of the second conductivity that the MOSFET operation is difficult to change to the IGBT operation can be avoided.

In the fourth semiconductor device of the invention, each of the collector region and the drain region preferably includes a plurality of sections separated from one another, and the sections of the collector region and the sections of the drain region are preferably alternately arranged along a direction vertical to a direction extending from the collector region toward the emitter/source region.

Thus, a collector voltage Vch at which the MOSFET operation is changed to the IGBT operation in the semiconductor device performing the MOSFET operation or the IGBT operation in accordance with the amount of collector current can be easily controlled by changing the length of each section of the collector region.

The second method for fabricating a semiconductor device of the invention is a method for fabricating the third or fourth semiconductor device of this invention and includes at least a step of forming the buried semiconductor layer and the collector region through one impurity implantation process.

In the second method for fabricating a semiconductor device, since the buried semiconductor layer and the collector region are formed through one and the same impurity implantation process, the number of procedures can be reduced as compared with the case where the buried semiconductor layer and the collector regions are individually formed, and hence, the cost can be reduced.

In each of the first through fourth semiconductor devices of the invention, when the gate insulating film (the first gate insulating film in the first or second semiconductor device) is formed to extend over the emitter region (the emitter/source region in the second or fourth semiconductor device), a short circuit between the gate electrode and the emitter region can be prevented.

As described so far, according to the present invention, the amount of excessive carriers remaining in the semiconductor substrate in turn off can be reduced, and hence, the time necessary for drawing the carriers can be shortened. Accordingly, the switching speed can be improved, so as to reduce the switching loss. As a result, a high-breakdown voltage semiconductor device in which the loss can be reduced in the whole region ranging from light load to heavy load can be realized. Specifically, the invention is very useful for application to, for example, a high-breakdown voltage switching device for used in a switched mode power supply apparatus.

### BRIEF DESCRIPTION OF THE DRAWINGS

FIG. 1 is a cross-sectional view of a semiconductor device according to Embodiment 1 of the invention.

FIG. 2 is a cross-sectional view for showing a procedure in a method for fabricating a semiconductor device according to Embodiment 1 of the invention.

FIG. 3 is a cross-sectional view for showing another procedure in the method for fabricating a semiconductor device according to Embodiment 1 of the invention.

FIG. 4 is a cross-sectional view for showing another procedure in the method for fabricating a semiconductor device according to Embodiment 1 of the invention.

FIG. 5 is a cross-sectional view for showing another procedure in the method for fabricating a semiconductor device according to Embodiment 1 of the invention.

FIG. 6 is a cross-sectional view for showing another procedure in the method for fabricating a semiconductor device according to Embodiment 1 of the invention.

FIG. 7 is a cross-sectional view for showing another procedure in the method for fabricating a semiconductor device according to Embodiment 1 of the invention.

FIG. 8A is a cross-sectional view (taken on line C-C′ of FIG. 8B) of a semiconductor device according to Embodiment 2 of the invention and FIG. 8B is a plan view of the semiconductor device of Embodiment 2.

FIG. 9 is a cross-sectional view (taken on line D-D′ of FIG. 8B) of the semiconductor device of Embodiment 2.

FIG. 10 is a diagram for showing temperature dependency of a fall time ft measured in the semiconductor device of Embodiment 2 and a semiconductor device of a comparative example.

FIG. 11 is a diagram for showing temperature dependency of on resistance Ron measured in the semiconductor device of Embodiment 2 and the semiconductor device of the comparative example.

FIG. 12A is a cross-sectional view (taken on line E-E′ of FIG. 12B) of a semiconductor device according to Embodiment 3 of the invention and FIG. 12B is a plan view of the semiconductor device of Embodiment 3.

FIG. 13 is a cross-sectional view for showing a procedure in a method for fabricating a semiconductor device according to Embodiment 3 of the invention.

FIG. 14 is a cross-sectional view for showing another procedure in the method for fabricating a semiconductor device according to Embodiment 3 of the invention.

FIG. 15 is a cross-sectional view for showing another procedure in the method for fabricating a semiconductor device according to Embodiment 3 of the invention.

FIG. 16 is a cross-sectional view for showing another procedure in the method for fabricating a semiconductor device according to Embodiment 3 of the invention.

FIG. 17 is a cross-sectional view for showing another procedure in the method for fabricating a semiconductor device according to Embodiment 3 of the invention.

FIG. 18 is a cross-sectional view for showing another procedure in the method for fabricating a semiconductor device according to Embodiment 3 of the invention.

FIG. 19 is a cross-sectional view of a semiconductor device according to Embodiment 4 of the invention.

FIG. 20 is a cross-sectional view for showing a procedure in a method for fabricating a semiconductor device according to Embodiment 4 of the invention.

FIG. 21 is a cross-sectional view for showing another procedure in the method for fabricating a semiconductor device according to Embodiment 4 of the invention.

FIG. 22 is a cross-sectional view for showing another procedure in the method for fabricating a semiconductor device according to Embodiment 4 of the invention.

FIG. 23 is a cross-sectional view for showing another procedure in the method for fabricating a semiconductor device according to Embodiment 4 of the invention.

FIG. 24 is a cross-sectional view for showing another procedure in the method for fabricating a semiconductor device according to Embodiment 4 of the invention.

FIG. 25 is a cross-sectional view for showing another procedure in the method for fabricating a semiconductor device according to Embodiment 4 of the invention.

FIG. 26 is a cross-sectional view of a semiconductor device according to Embodiment 5 of the invention.

FIG. 27 is a cross-sectional view for showing a procedure in a method for fabricating a semiconductor device according to Embodiment 5 of the invention.

FIG. 28 is a cross-sectional view for showing another procedure in the method for fabricating a semiconductor device according to Embodiment 5 of the invention.

FIG. 29 is a cross-sectional view for showing another procedure in the method for fabricating a semiconductor device according to Embodiment 5 of the invention.

FIG. 30 is a cross-sectional view for showing another procedure in the method for fabricating a semiconductor device according to Embodiment 5 of the invention.

FIG. 31 is a cross-sectional view for showing another procedure in the method for fabricating a semiconductor device according to Embodiment 5 of the invention.

FIG. 32 is a cross-sectional view for showing another procedure in the method for fabricating a semiconductor device according to Embodiment 5 of the invention.

FIG. 33A is a cross-sectional view (taken on line A-A′ of FIG. 33B) of a semiconductor device of a comparative example and FIG. 33B is a plan view of the semiconductor device of the comparative example.

FIG. 34 is a cross-sectional view (taken on line B-B′ of FIG. 33B) of the semiconductor device of the comparative example.

FIG. 35 is a diagram for showing the correlation between a collector voltage and a collector current obtained in the semiconductor device of the comparative example.

FIG. 36 is a diagram for showing an exemplified circuit configuration of a conventional switched power supply apparatus.

FIG. 37 is a diagram for showing the comparison, in the relationship between load and loss, between a MOSFET (of a lateral type having a drift region with a resurf structure) and an IGBT (of a lateral type) used in a switched mode power supply apparatus.

FIG. 38 is a cross-sectional view of an example of a conventional shorted-anode lateral type IGBT.

### DETAILED DESCRIPTION OF THE INVENTION

### Embodiment 1

A semiconductor device according to Embodiment 1 of the invention, that is, a high-breakdown voltage semiconductor switching device specifically, will now be described with reference to the accompanying drawings.

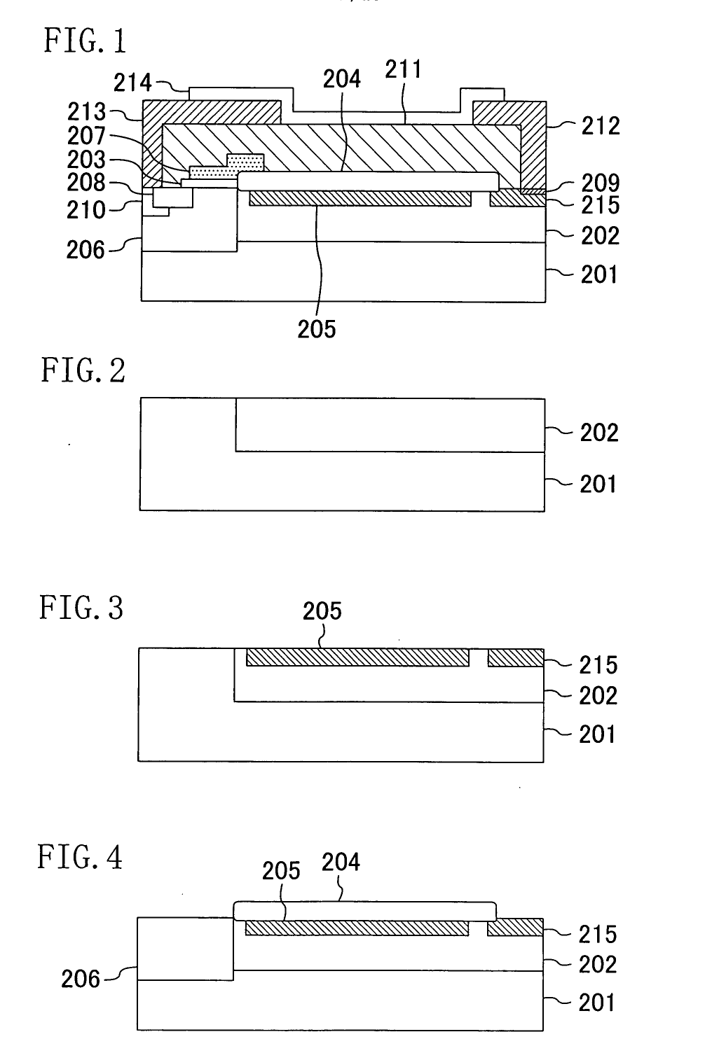

FIG. 1 shows the cross-sectional structure of the semiconductor device of Embodiment 1. As shown in FIG. 1, a resurf region 202 of, for example, N-type conductivity (with, for example, an impurity concentration of 1×10¹⁶/cm³ and a depth of 7 μm) is formed in a surface portion of a semiconductor substrate 201 of, for example, P⁻-type conductivity (with, for example, an impurity concentration of 1×10¹⁴/cm³). Furthermore, a base region 206 of, for example, P-type conductivity (with, for example, an impurity concentration of 1×10¹⁶/cm³ and a depth of 4 μm) is formed in a surface portion of the semiconductor substrate 201 to be adjacent to the resurf region 202.

In the base region 206, a contact region 210 of, for example, P⁺-type conductivity (with, for example, an impurity concentration of 1×10¹⁹/cm³ and a depth of 2 μm) and an emitter region 208 of, for example, N⁺-type conductivity (with, for example, an impurity concentration of 1×10²⁰/cm³ and a depth of 0.5 μm) are formed to be spaced from the resurf region 202. Also, a gate insulating film 203 is formed so as to cover a portion of the base region 206 disposed between the emitter region 208 and the resurf region 202, and a gate electrode 207 is formed on the gate insulating film 203.

When the gate insulating film 203 is formed to extend over the emitter region 208, a short circuit between the gate electrode 207 and the emitter region 208 can be prevented.

Furthermore, a top semiconductor layer 205 of, for example, P-type conductivity (with, for example, an impurity concentration of 1×10¹⁶/cm³ and a depth of 1 μm) is formed in a surface portion of the resurf region 202. Although not shown in the drawing, the top semiconductor layer 205 is electrically connected to the base region 206 through a given portion of the resurf region 202, an upper layer interconnect or the like.

Also, a collector region 215 of, for example, P-type conductivity (with, for example, an impurity concentration of 1×10¹⁶/cm³ and a depth of 1 μm) is formed in a surface portion of the resurf region 202 to be spaced from the top semiconductor layer 205. At this point, the collector region 215 has substantially the same impurity concentration as and is disposed at substantially the same depth as the top semiconductor layer 205.

A collector contact region 209 of, for example, P⁺-type conductivity (with, for example, an impurity concentration of 1×10¹⁹/cm³ and a depth of 0.5 μm) is formed in a surface portion of the collector region 215. It is noted that the collector contact region 209 can be omitted.

An interlayer film 211 is formed above the semiconductor substrate 201 having the aforementioned various impurity regions and the like with a field insulating film 204 formed between the semiconductor substrate 201 including the resurf region 202 and the interlayer film 211.

Above the semiconductor substrate 201, a collector electrode 212 penetrating the interlayer film 211 and electrically connected to the collector contact region 209 (i.e., the collector region 215) is formed, and an emitter electrode 213 penetrating the interlayer film 211 and electrically connected to both the contact region 210 (i.e., the base region 206) and the emitter region 208 is formed.

A protective film 214 is formed on the interlayer film 211 on which the collector electrode 212 and the emitter electrode 213 are formed.

In the semiconductor device of this embodiment, in the case where a positive voltage is applied to the gate electrode 207 with positive bias applied between the collector electrode 212 and the emitter electrode 213 (with a side of the collector electrode 212 set to high potential), holes are injected from the collector region 215 to the resurf region 202 when a potential difference caused between the potential of the collector region 215 and the potential of a portion of the resurf region 202 surrounding the collector region 215 becomes approximately 0.6 V, and thus, an IGBT operation is started.

In other words, the semiconductor device (the switching device) of this embodiment is a lateral type IGBT. In this IGBT, the impurity concentration in the collector region 215 is set to be as low as the impurity concentration in the top semiconductor layer 205, and therefore, as compared with the case where the collector region is made of a high concentration layer (a P⁺-type layer), the amount of excessive carriers injected into the semiconductor substrate 201 including the resurf region 202 during the IGBT operation can be suppressed. As a result, the amount of excessive carriers remaining in the semiconductor substrate 201 in turn off can be so reduced that time necessary for drawing the carriers can be shortened, and hence, the switching speed can be improved, resulting in reducing switching loss. In other words, a high-breakdown voltage semiconductor device in which loss can be reduced in the whole region ranging from light load to heavy load can be realized.

Moreover, in the case where the collector region is made of a high concentration layer, it is necessary to provide a buffer layer of, for example, N-type conductivity with a higher impurity concentration than the resurf region between the collector region and the resurf region for reducing the efficiency for injecting holes from the collector region to the resurf region. On the contrary, since the collector region 215 is formed to have a low concentration in the semiconductor device of this embodiment, there is no need to provide such an N-type buffer layer, and hence, the fabrication process can be simplified.

Now, an exemplified method for fabricating the switching device of this embodiment shown in FIG. 1 will be described with reference to cross-sectional views of FIGS. 2 through 7.

First, in a procedure shown in FIG. 2, a resurf region 202 of, for example, N-type conductivity is selectively formed by, for example, phosphorous ion implantation in a surface portion of a P⁻-type semiconductor substrate 201 with an impurity concentration of, for example, approximately 1×10¹⁴/cm³. The impurity concentration in the resurf region 202 is, for example, approximately 1×10¹⁶/cm³, and the depth of the resurf region 202 is, for example, approximately 7 μm.

Next, in a procedure shown in FIG. 3, a top semiconductor layer 205 of, for example, P-type conductivity and a collector region 215 of, for example, P-type conductivity are simultaneously and selectively formed by, for example, boron ion implantation in surface portions of the resurf region 202. At this point, the top semiconductor layer 205 and the collector region 215 are spaced from each other. Also, the impurity concentration in the top semiconductor layer 205 and the collector region 215 is, for example, approximately 1×10¹⁶/cm³, and the depth of the top semiconductor layer 205 and the collector region 215 is, for example, approximately 1 μm.

It is noted that the top semiconductor layer 205 is electrically connected to a base region 206 described below although not shown in the drawing.

Then, in a procedure shown in FIG. 4, the base region 206 of, for example, P-type conductivity is formed by, for example, boron ion implantation in a surface portion of the semiconductor substrate 201. The base region 206 is formed to be adjacent to the resurf region 202. The impurity concentration in the base region 206 is, for example, 1×10¹⁶/cm³, and the depth of the base region 206 is, for example, 4 μm. Furthermore, a field insulating film 204 with a thickness of, for example, 500 nm is formed on the resurf region 202 by, for example, wet oxidation or the like. At this point, the impurity of the top semiconductor layer 205 is diffused so that its impurity concentration can be slightly lowered.

It is noted that the order of performing ion implantation for forming the respective impurity regions of this embodiment is not particularly specified.

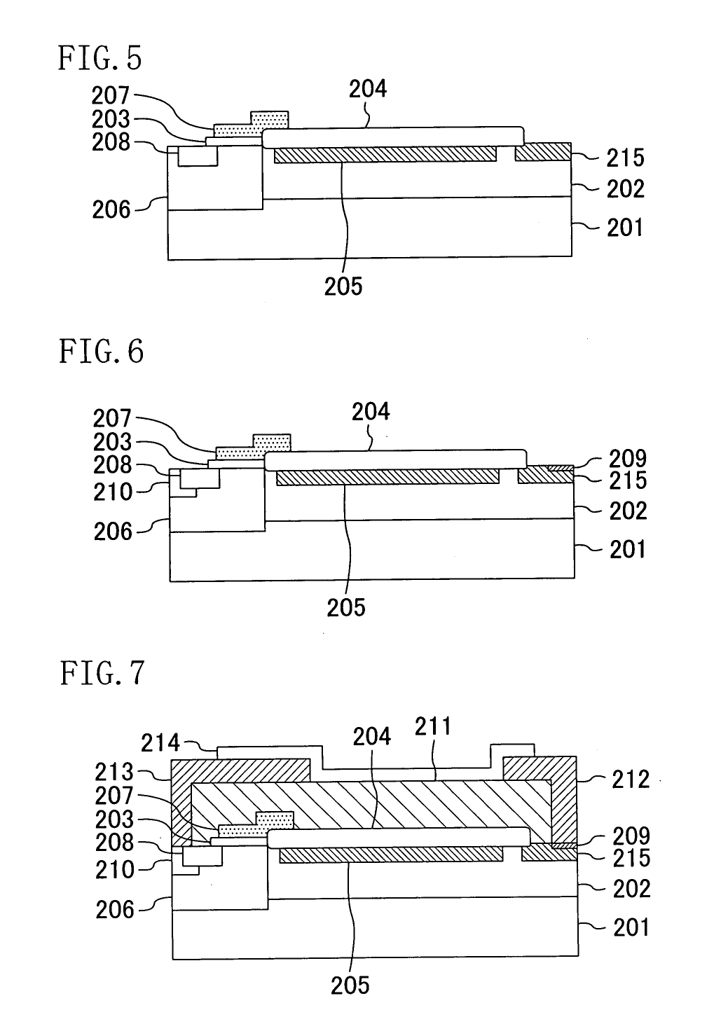

Next, in a procedure shown in FIG. 5, a gate insulating film 203 is formed by, for example, thermal oxidation so as to cover a portion of the base region 206 disposed between an emitter region 208 described below and the resurf region 202. Thereafter, a gate electrode 207 made of, for example, polysilicon is selectively formed on the gate insulating film 203. Furthermore, the emitter region 208 of, for example, N⁺-type conductivity is selectively formed in the base region 206 in a self-alignment manner by, for example, arsenic ion implantation with the gate electrode 207 used as a mask. The emitter region 208 is spaced from the resurf region 202. The impurity concentration in the emitter region 208 is, for example, approximately 1×10²⁰/cm³, and the depth of the emitter region 208 is, for example, approximately 0.5 μm.

Then, in a procedure shown in FIG. 6, a contact region 210 of, for example, P⁺-type conductivity is formed by, for example, boron ion implantation in the base region 206. The contact region 210 is spaced from the resurf region 202. The impurity concentration in the contact region 210 is, for example, approximately 1×10¹⁹/cm³, and the depth of the contact region 210 is, for example, 2 μm. Thereafter, a collector contact region 209 of, for example, P⁺-type conductivity is formed by, for example, boron ion implantation, in a surface portion of the collector region 215. The impurity concentration in the collector contact region 209 is, for example, approximately 1×10¹⁹/cm³, and the depth of the collector contact region 209 is, for example, 0.5 μm. It is noted that the collector contact region 209 may be omitted.

Next, in a procedure shown in FIG. 7, an interlayer film 211 is formed by, for example, atmospheric pressure CVD (chemical vapor deposition) above the semiconductor substrate 201 including portions on the field insulating film 204 and the gate electrode 207. Thereafter, an opening is formed in a given portion of the interlayer film 211, so as to form, above the semiconductor substrate 201, a collector electrode 212 electrically connected to the collector contact region 209 (i.e., the collector region 215) and an emitter electrode 213 electrically connected to both the contact region 210 (i.e., the base region 206) and the emitter region 208. Ultimately, after forming a protective film 214 made of, for example, a plasma SiN film on the interlayer film 211, an opening is formed in a pad forming region of the protective film 214. In this manner, the switching device of this embodiment shown in FIG. 1 is completed.

In the fabrication method of this embodiment described above, the top semiconductor layer 205 and the collector region 215 are formed in one and the same impurity implantation process, and therefore, the number of procedures can be reduced and the cost can be lowered as compared with the case where they are individually formed.

### COMPARATIVE EXAMPLE

As a power semiconductor device with a high voltage and high power having low on resistance and a high switching off speed, a structure composed of a lateral double diffused MOS (LDMOS) and a lateral insulating gate bipolar transistor (LIGBT) both formed on the same substrate has been proposed (see, for example, Patent Document 7).

A semiconductor device of Patent Document 7 has a double gate structure in which a gate of an LIGBT and a gate of an LDMOS are individually provided and an anode of the LIGBT and a drain of the LDMOS are isolated from each other by a trench well.

Apart from the semiconductor device of Patent Document 7, the present inventor has proposed, in Patent Document 8, a single gate lateral type IGBT structure capable of performing both the MOSFET operation and the IGBT operation with a simple structure not using trench well isolation.

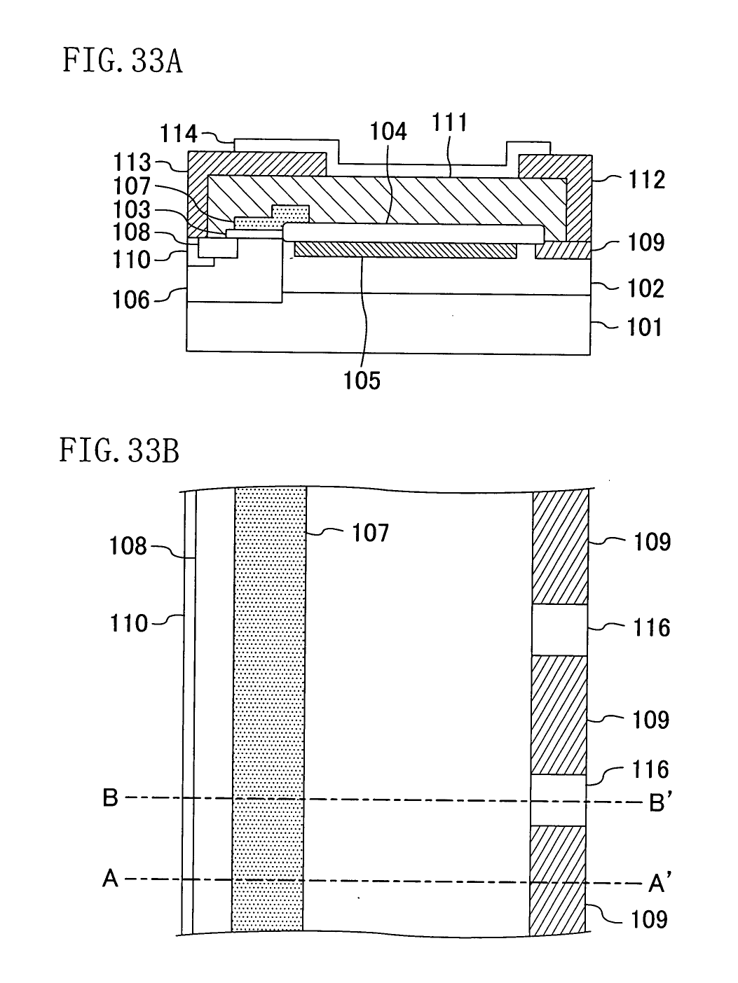

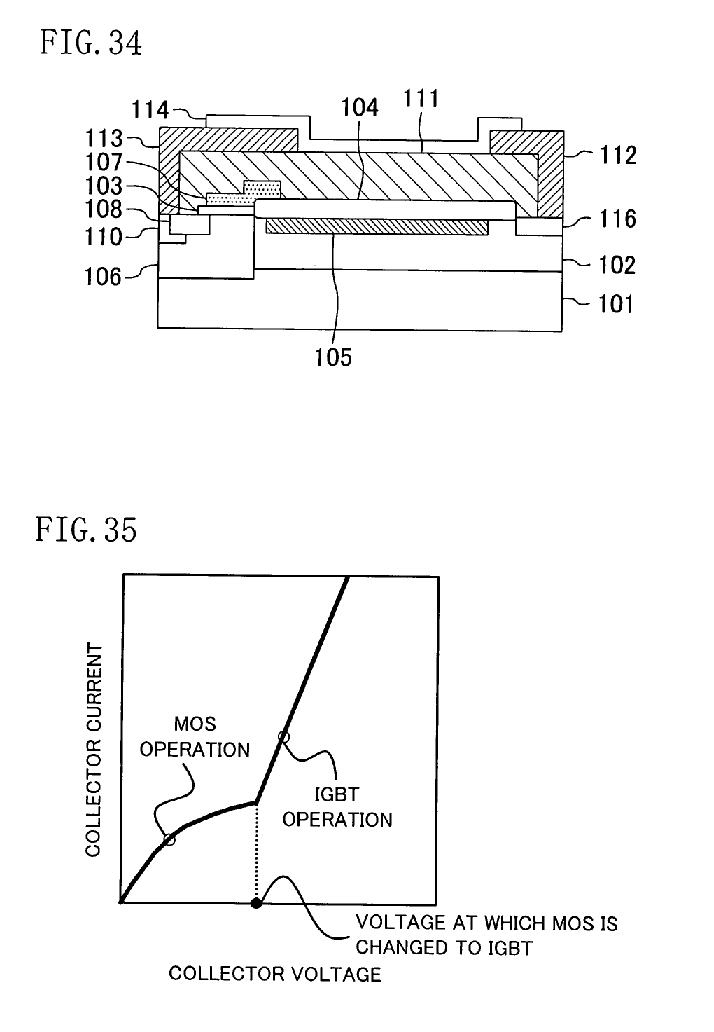

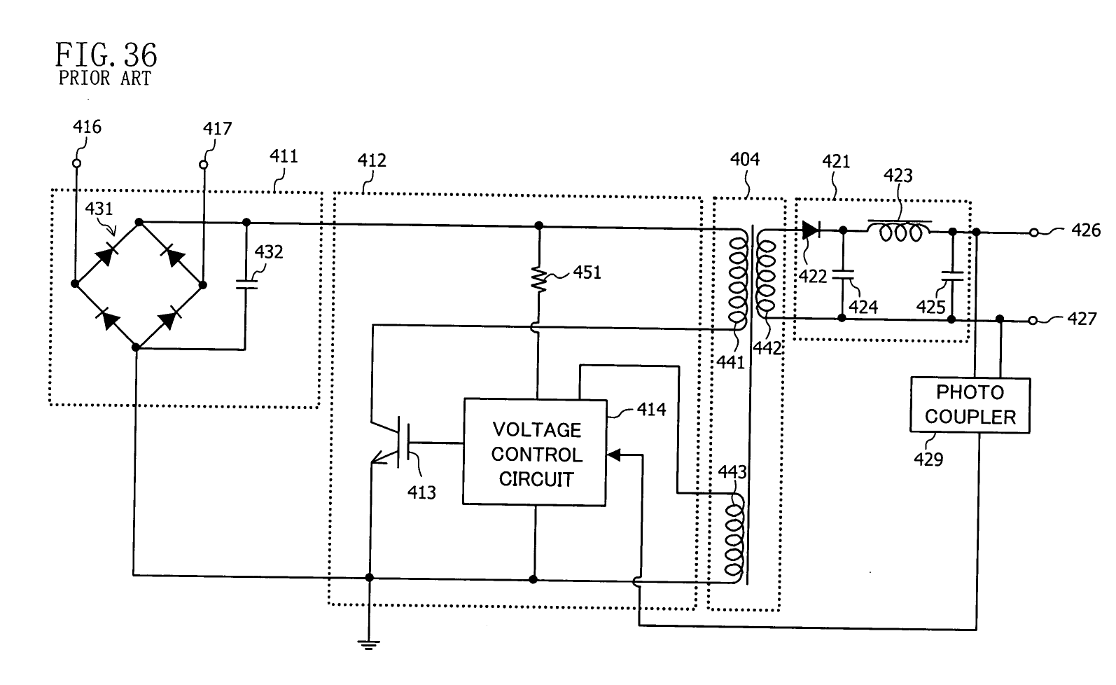

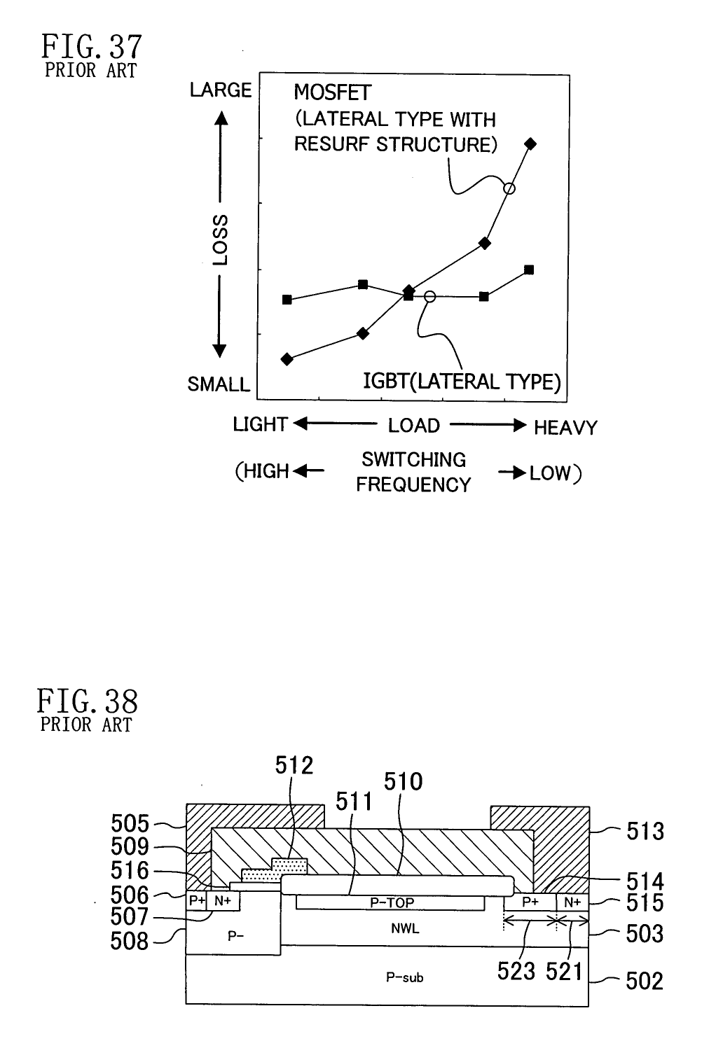

Now, a semiconductor device having the IGBT structure proposed by the present inventor will be described as a comparative example with reference to the accompanying drawings. FIG. 33A and FIG. 34 are cross-sectional views of the semiconductor device of the comparative example, and FIG. 33B is a plan view of the semiconductor device of the comparative example. It is noted that the FIG. 33A is a cross-sectional view taken on line A-A′ of FIG. 33B and that FIG. 34 is a cross-sectional view taken on line B-B′ of FIG. 33B. Also, a part of composing elements is omitted in FIG. 33B.

As shown in FIGS. 33A, 33B and 34, an N-type resurf region 102 (with, for example, an impurity concentration of 1×10¹⁶/cm³ and a depth of 7 μm) is formed in a surface portion of a P⁻-type semiconductor substrate 101 (with, for example, an impurity concentration of 1×10¹⁴/cm³). Furthermore, a P-type base region 106 (with, for example, an impurity concentration of 1×10¹⁶/cm³ and a depth of 4 μm) is formed in a surface portion of the semiconductor substrate 101 to be adjacent to the resurf region 102.

In the base region 106, a P⁺-type contact region 110 (with, for example, an impurity concentration of 1×10¹⁹/cm³ and a depth of 2 μm) and an N⁺-type emitter/source region 108 (with, for example, an impurity concentration of 1×10²⁰/cm³ and a depth of 0.5 μm) are formed to be spaced from the resurf region 102. Furthermore, a gate insulating film 103 is formed so as to cover a portion of the base region 106 disposed between the emitter/source region 108 and the resurf region 102, and a gate electrode 107 is formed on the gate insulating film 103.

On the other hand, a P-type top semiconductor layer 105 (with, for example, an impurity concentration of 1×10¹⁶/cm³ and a depth of 1 μm) electrically connected to the base region 106 is formed in a surface portion of the resurf region 102.

A P⁺-type collector region 109 (with, for example, an impurity concentration of 1×10¹⁹/cm³ and a depth of 1 μm) is formed in a surface portion of the resurf region 102 to be spaced from the top semiconductor layer 105 (see FIG. 33A in particular). At this point, the collector region 109 is formed to have a much higher concentration than the top semiconductor layer 105 for reducing the on resistance.

Furthermore, an N⁺-type drain region 116 (with, for example, 1×10²⁰/cm³ and a depth of 0.5 μm) electrically connected to the collector region 109 is formed in a surface portion of the resurf region 102 to be spaced from the top semiconductor layer 105 (see FIG. 34 in particular).

At this point, as shown in FIG. 33B, each of the collector region 109 and the drain region 116 includes a plurality of sections separated from one another. Also, along a direction vertical to a direction extending from the collector region 109 toward the emitter/source region 108, the sections of the collector region 109 and the sections of the drain region 116 are alternately arranged.

An interlayer film 111 is formed above the semiconductor substrate 101 including the aforementioned various impurity regions and the like with a field insulating film 104 formed between the semiconductor substrate 101 including the resurf region 102 and the interlayer film 111.

Above the semiconductor substrate 101, a collector/drain electrode 112 penetrating the interlayer film 111 and electrically connected to both the collector region 109 and the drain region 116 is formed, and an emitter/source electrode 113 penetrating the interlayer film 111 and electrically connected to both the contact region 110 (i.e., the base region 106) and the emitter/source region 108 is formed.

A protective film 114 is formed on the interlayer film 111 on which the collector/drain electrode 112 and the emitter/source electrode 113 are formed.

In the semiconductor device of the comparative example, when a positive voltage is applied to the gate electrode 107 with positive bias (hereinafter sometimes referred to as the collector voltage) applied between the collector/drain electrode 112 and the emitter/source electrode 113, an electron current (hereinafter sometimes referred to as the collector current) flows from the drain region 116 toward the emitter/source electrode 113, and thus, a MOSFET operation is performed. Moreover, when the electron current, i.e., the collector current, flowing toward the emitter/source electrode 113 is increased to some extent and a potential difference caused between the potential of the collector region 109 and the potential of a portion of the resurf region 102 surrounding the collector region 109 becomes approximately 0.6 V, holes are injected from the collector region 109 to the resurf region 102, and thus, the MOSFET operation is changed to an IGBT operation. FIG. 35 shows the correlation between the collector voltage and the collector current obtained in the semiconductor device of the comparative example.

In this manner, in the semiconductor device of the comparative example, when the collector current flowing in the device is comparatively small, the MOSFET operation can be performed while the IGBT operation can be performed when the collector current flowing in the device is increased to some extent. In other words, a semiconductor device capable of performing the MOSFET operation or the IGBT operation in accordance with the amount of collector current flowing in the device can be realized.

In the semiconductor device of the comparative example, each of the collector region 109 and the drain region 116 includes a plurality of sections separated from one another, and the sections of the collector region 109 and the sections of the drain region 116 are alternately arranged along the direction vertical to the direction extending from the collector region 109 toward the emitter/source region 108. In this manner, the length of the collector region 109 along the vertical direction (i.e., the direction along which the collector region 109 and the drain region 116 are arranged) can be reduced. Therefore, a collector voltage at which the MOSFET operation is changed to the IGBT operation (namely, a collector voltage (of, for example, approximately 1 V) at which the potential difference caused between the potential of the collector region and the potential of the portion of the resurf region surrounding the collector region becomes approximately 0.6 V through voltage drop) can be easily increased. Accordingly, more practical design can be attained by controlling a collector voltage at which the MOSFET operation is changed to the IGBT operation so as to, for example, increase the range of the collector voltage at which the MOSFET operation can be performed with high speed switching performance (namely, so as to design the device to perform the MOSFET operation with high speed switching performance until the collector voltage exceeds, for example, approximately 1 V). In other words, balance between the MOSFET operation with a good switching characteristic and the IGBT operation with low conducting resistance can be freely designed.

In the aforementioned semiconductor device of the comparative example performing the MOSFET operation or the IGBT operation, however, the following problem occurs during the IGBT operation.

The conductivity is modulated in an IGBT in the same manner as in a bipolar transistor, and hence, the conducting loss can be reduced. Therefore, as compared with a MOSFET with an equivalent chip size, the power loss can be reduced in the IGBT.

In the semiconductor device of the comparative example, however, since the collector region 109 is formed to have a much higher concentration than the top semiconductor layer 105 for reducing the on resistance, it takes longer time to draw excessive carriers remaining within the semiconductor substrate 101 at the time of turn off when an on state is switched to an off state. Therefore, the switching speed of the IGBT is lower than the switching speed of the MOSFET, and as a result, the switching loss is increased, which leads to a problem that the power loss cannot be sufficiently reduced.

In order to cope with such a problem, application of, for example, life time killing technique or the like may be employed for improving the switching speed of the IGBT. However, in this case, the cost is increased and the characteristic is degraded, and hence, this means cannot be a good way to solve the problem.

Moreover, in the semiconductor device of the comparative example, since the collector region 109 is formed to have a much higher concentration than the top semiconductor layer 105, it is necessary to provide an N-type buffer layer with a higher impurity concentration than the resurf region 102 between the collector region 109 and the resurf region 102 for reducing the efficiency for injecting holes from the collector region 109 to the resurf region 102. This increases the number of fabrication procedures and leads to another problem that the MOSFET operation is difficult to change to the IGBT operation.

In a semiconductor device according to Embodiment 2 of the invention described below, the problems of the semiconductor device of the comparative example can be solved without increasing the cost and degrading the characteristics.

### Embodiment 2

The semiconductor device according to Embodiment 2 of the invention, that is, a high-breakdown voltage semiconductor switching device specifically, will now be described with reference to the accompanying drawings.

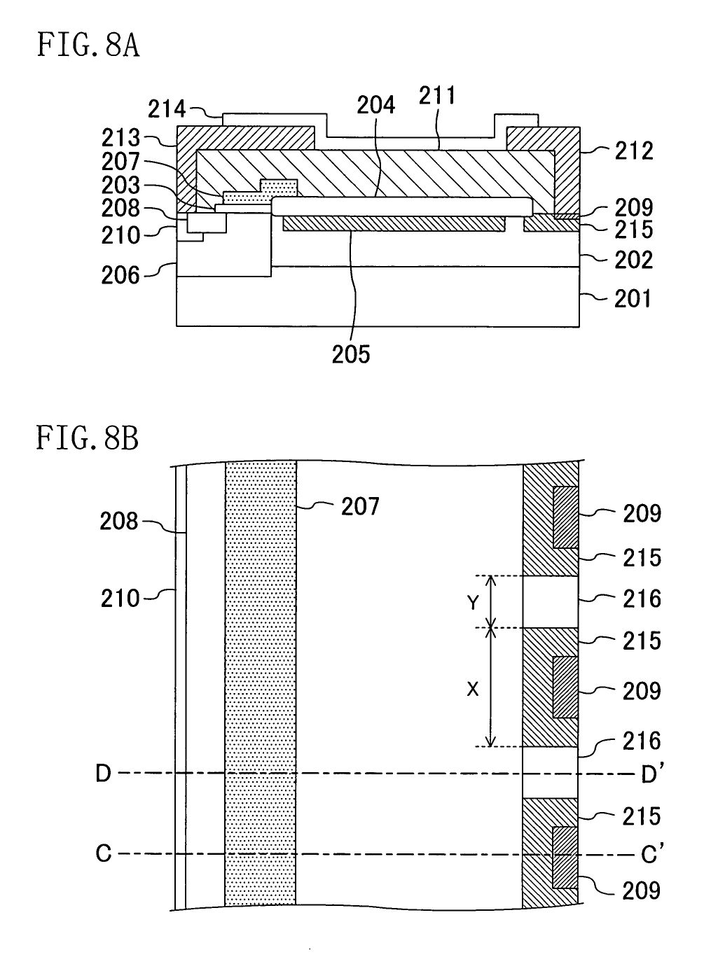

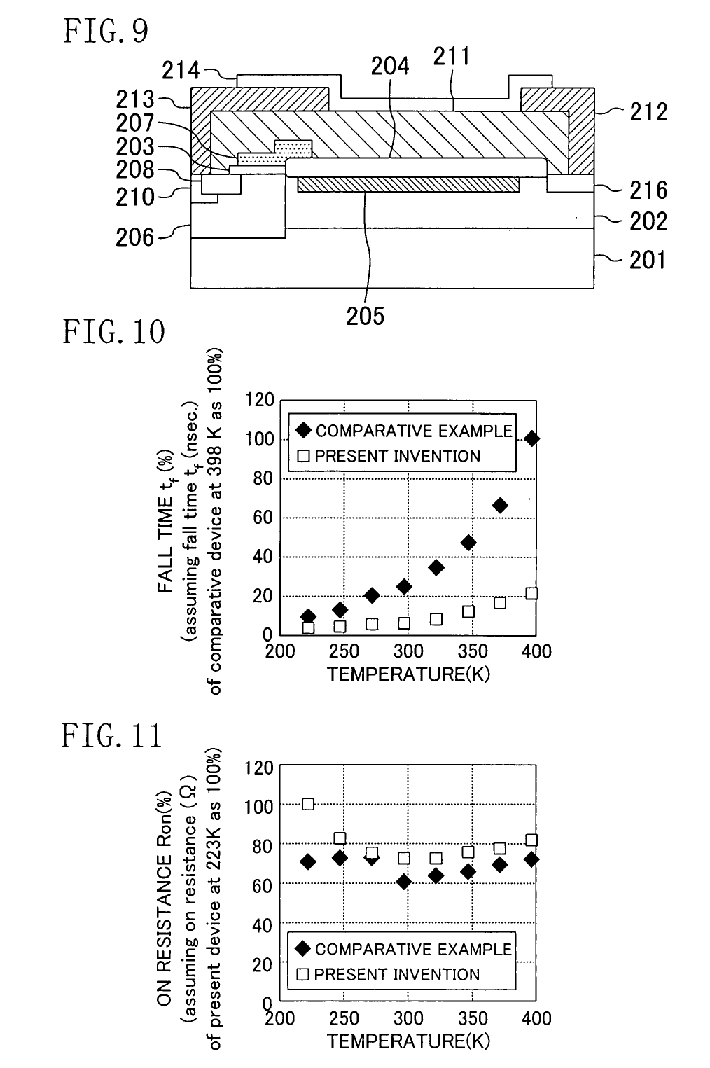

FIGS. 8A and 9 are cross-sectional views of the semiconductor device of Embodiment 2, and FIG. 8B is a plan view of the semiconductor device of Embodiment 2. It is noted that FIG. 8A is a cross-sectional view taken on line C-C′ of FIG. 8B and that FIG. 9 is a cross-sectional view taken on line D-D′ of FIG. 8B. Also, a part of composing elements is omitted in FIG. 8B.

As shown in FIGS. 8A, 8B and 9, a resurf region 202 of, for example, N-type conductivity (with, for example, an impurity concentration of 1×10¹⁶/cm³ and a depth of 7 μm) is formed in a surface portion of a semiconductor substrate 201 of, for example, P⁻-type conductivity (with, for example, an impurity concentration of 1×10¹⁴/cm³). Furthermore, a P-type base region 206 (with, for example, an impurity concentration of 1×10¹⁶/cm³ and a depth of 4 μm) is formed in a surface portion of the semiconductor substrate 201 to be adjacent to the resurf region 202.

In the base region 206, a contact region 210 of, for example, P⁺-type conductivity (with, for example, an impurity concentration of 1×10¹⁹/cm³ and a depth of 2 μm) and an emitter/source region 208 of, for example, N⁺-type conductivity (with, for example, an impurity concentration of 1×10²⁰/cm³ and a depth of 0.5 μm) are formed to be spaced from the resurf region 202. Also, a gate insulating film 203 is formed so as to cover a portion of the base region 206 disposed between the emitter/source region 208 and the resurf region 202, and a gate electrode 207 is formed on the gate insulating film 203.

When the gate insulating film 203 is formed to extend over the emitter/source region 208, a short circuit between the gate electrode 207 and the emitter/source region 208 can be prevented.

Furthermore, a top semiconductor layer 205 of, for example, P-type conductivity (with, for example, an impurity concentration of 1×10¹⁶/cm³ and a depth of 1 μm) is formed in a surface portion of the resurf region 202. Although not shown in the drawing, the top semiconductor layer 205 is electrically connected to the base region 206 through a given portion of the resurf region 202, an upper layer interconnect or the like.

Also, a collector region 215 of, for example, P-type conductivity (with, for example, an impurity concentration of 1×10¹⁶/cm³ and a depth of 1 μm) is formed in a surface portion of the resurf region 202 to be spaced from the top semiconductor layer 205. At this point, the collector region 215 has substantially the same impurity concentration as and is disposed at substantially the same depth as the top semiconductor layer 205.

A collector contact region 209 of, for example, P⁺-type conductivity (with, for example, an impurity concentration of 1×10¹⁹/cm³ and a depth of 0.5 μm) is formed in a surface portion of the collector region 215. It is noted that the collector contact region 209 can be omitted.

Furthermore, a drain region 216 of, for example, N⁺-type conductivity (with, for example, an impurity concentration of 1×10²⁰/cm³ and a depth of 0.5 μm) is formed in a surface portion of the resurf region 202 to be spaced from the top semiconductor layer 205.

At this point, each of the collector region 215 and the drain region 216 includes a plurality of sections separated from one another as shown in FIG. 8B. Also, the sections of the collector region 215 and the sections of the drain region 216 are alternately arranged along a direction vertical to a direction extending from the collector region 215 toward the emitter/source region 208 (hereinafter sometimes simply referred to as the vertical direction). The length of each section of the collector region 215 along the vertical direction (corresponding to a length X of FIG. 8B) is, for example, approximately 60 μm, and the length of each section of the drain region 216 along the vertical direction (corresponding to a length Y of FIG. 8B) is, for example, approximately 30 μm.

An interlayer film 211 is formed above the semiconductor substrate 201 having the aforementioned various impurity regions and the like with a field insulating film 204 formed between the semiconductor substrate 201 including the resurf region 202 and the interlayer film 211.

Above the semiconductor substrate 201, a collector/drain electrode 212 penetrating the interlayer film 211 and electrically connected to both the collector contact region 209 (i.e., the collector region 215) and the drain region 216 is formed, and an emitter/source electrode 213 penetrating the interlayer film 211 and electrically connected to both the contact region 210 (i.e., the base region 206) and the emitter/source region 208 is formed.

A protective film 214 is formed on the interlayer film 211 on which the collector/drain electrode 212 and the emitter/source electrode 213 are formed.

In the semiconductor device of this embodiment, in the case where a positive voltage is applied to the gate electrode 207 with positive bias (hereinafter sometimes referred to as the collector voltage) applied between the collector/drain electrode 212 and the emitter/source electrode 213, an electron current (hereinafter sometimes referred to as the collector current) flows from the drain region 216 toward the emitter/source electrode 213, and thus, a MOSFET operation is performed. Furthermore, when the electron current, namely, the collector current, flowing toward the emitter/source electrode 213 is increased to some extent and a potential difference caused between the potential of the collector region 215 and the potential of a portion of the resurf region 202 surrounding the collector region 215 becomes approximately 0.6 V, holes are injected from the collector region 215 to the resurf region 202, and thus, the MOSFET operation is changed to an IGBT operation.

In this manner, in the semiconductor device of this embodiment, the MOSFET operation can be performed when the collector current flowing in the device is comparatively small, and the IGBT operation can be performed when the collector current flowing in the device is increased to some extent. In other words, a semiconductor device capable of performing the MOSFET operation or the IGBT operation in accordance with the amount of collector current flowing in the device can be realized. Furthermore, in the semiconductor device of this embodiment, the impurity concentration in the collector region 215 is set to be as low as the impurity concentration in the top semiconductor layer 205, and hence, as compared with the case where the collector region is made of a high concentration layer (a P⁺-type layer) (as in the comparative example), the amount of excessive carriers injected into the semiconductor substrate 201 including the resurf region 202 during the IGBT operation can be suppressed. As a result, the amount of excessive carriers remaining in the semiconductor substrate 201 in turn off can be reduced so as to shorten the time necessary for drawing the carriers. Therefore, the switching speed can be improved, so as to reduce the switching loss. In other words, a high-breakdown voltage semiconductor device in which the loss is reduced in the whole region ranging from light load to heavy load can be realized.

FIG. 10 is a graph obtained by plotting dependency of a fall time tf (i.e., a time required after turn off for the collector current to reduce from 90% of its value attained immediately before the turn off to 10%) on a temperature (K) obtained in the semiconductor device of this embodiment shown in FIGS. 8A, 8B and 9 (i.e., the device including the collector region 215 made of a P-type semiconductor layer (with an impurity concentration of 1×10¹⁶/cm³ and a depth of 1 μm)) and in the semiconductor device of the comparative example shown in FIGS. 33A, 33B and 34 (i.e., the device including the collector region 109 made of a P⁺-type semiconductor layer (with an impurity concentration of 1×10¹⁹/cm³ and a depth of 1 μm)). In FIG. 10, the abscissa indicates the temperature (K) and the ordinate indicates the fall time tf. Also, the fall time tf is expressed as a percentage calculated by assuming the fall time tf (nsec.) of the semiconductor device of the comparative example attained at a temperature of 398 K as 100%.

As shown in FIG. 10, in the semiconductor device of this invention in which the impurity concentration in the collector region 215 is substantially as low as the impurity concentration in the P-type top semiconductor layer 205, the fall time tf is remarkably improved at each temperature as compared with that of the comparative example in which the collector region is made of the P⁺-type semiconductor layer.

FIG. 11 is a graph obtained by plotting dependency of the on resistance Ron on the temperature (K) measured in the semiconductor device of this embodiment shown in FIGS. 8A, 8B and 9 (i.e., the device including the collector region 215 made of a P-type semiconductor layer (with an impurity concentration of 1×10¹⁶/cm³ and a depth of 1 μm)) and in the semiconductor device of the comparative example shown in FIGS. 33A, 33B and 34 (i.e., the device including the collector region 109 made of a P⁺-type semiconductor layer (with an impurity concentration of 1×10¹⁹/cm³ and a depth of 1 μm)). In FIG. 11, the abscissa indicates the temperature (K) and the ordinate indicates the on resistance Ron. Also, the on resistance Ron is expressed as a percentage calculated by assuming the on resistance Ron (Ω) of the semiconductor device of this embodiment attained at a temperature of 223 K as 100%.

As shown in FIG. 11, also in the semiconductor device of this embodiment in which the impurity concentration in the collector region 215 is substantially as low as the impurity concentration in the P-type top semiconductor layer 205, the on resistance has a value equivalent to that of the comparative example in which the collector region is made of the P⁺-type semiconductor layer. Although the on resistance of the semiconductor device of this embodiment is slightly high at a temperature lower than 250 K, this does not cause any problem because the range of the practical use is approximately 250 K through 400 K (i.e., approximately −20° C. through 140° C.).

It is understood from the above-described measurement results shown in FIGS. 10 and 11 that the semiconductor device of this embodiment in which the impurity concentration in the collector region 215 is substantially as low as the impurity concentration in the P-type top semiconductor layer 205 attains an effect to largely reduce the switching loss without substantially increasing loss derived from the on resistance Ron.

Moreover, in the comparative example in which the collector region is made of the high concentration layer (the P⁺-type semiconductor layer), it is necessary to provide an N-type buffer layer with a higher impurity concentration than the resurf region between the collector region and the resurf region for reducing the efficiency for injecting holes from the collector region to the resurf region. On the contrary, since the collector region 215 is formed to have a low concentration in the semiconductor device of this embodiment, there is no need to provide such an N-type buffer layer, which can simplify the fabrication process. Furthermore, the problem of the comparative example that it is difficult to change the MOSFET operation to the IGBT operation because of the N-type buffer layer can be avoided.

In a fabrication method for the semiconductor device (the switching device) of this embodiment shown in FIGS. 8A, 8B and 9, procedures for forming the cross-sectional structure taken on line C-C′ of FIG. 8B (namely, the cross-sectional structure of FIG. 8A) can be similarly performed to the procedures of Embodiment 1 shown in FIGS. 2 through 7 and hence the description is omitted. Also, procedures for forming the cross-sectional structure taken on line D-D′ of FIG. 8B (namely, the cross-sectional structure of FIG. 9) can be performed by changing the mask layout so as to form the N⁺-type drain region 216 simultaneously with the N⁺-type emitter region 208 in the procedure of Embodiment 1 shown in FIG. 5. It is noted that the impurity concentration in the drain region 216 is, for example, approximately 1×10²⁰/cm³ and the depth of the drain region 216 is, for example, approximately 0.5 μm.

### Embodiment 3

The semiconductor device according to Embodiment 3 of the invention, that is, a high-breakdown voltage semiconductor switching device specifically, will now be described with reference to the accompanying drawings.

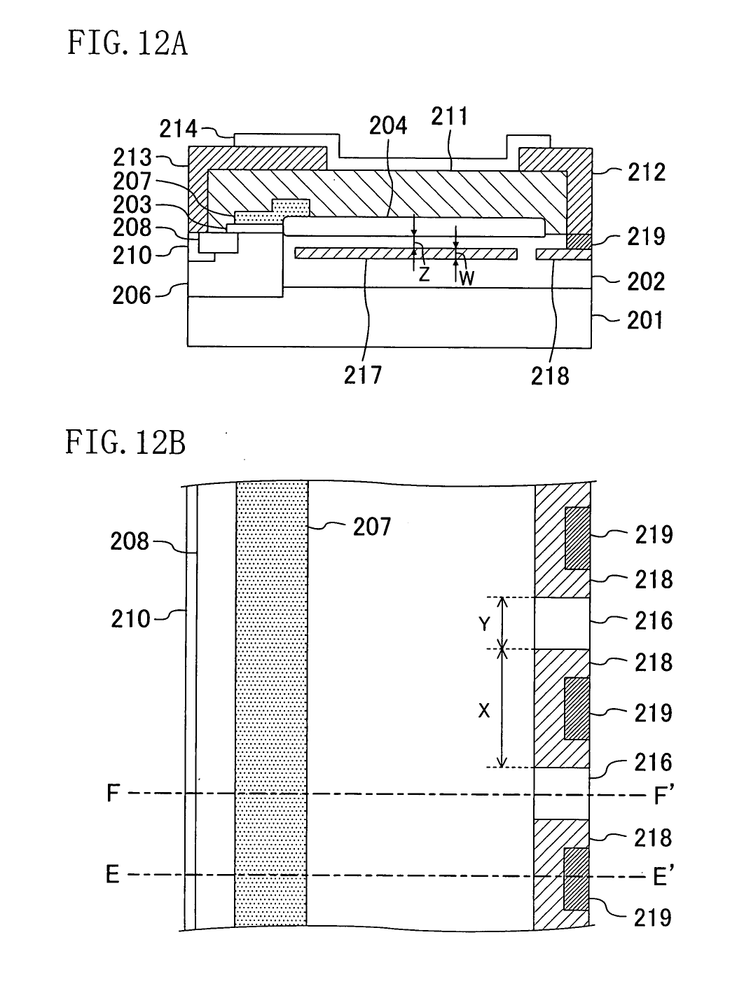

FIG. 12A is a cross-sectional view of the semiconductor device of Embodiment 3, and FIG. 12B is a plan view of the semiconductor device of Embodiment 3. It is noted that FIG. 12A is a cross-sectional view taken on line E-E′ of FIG. 12B. Furthermore, a cross-sectional view taken on line F-F′ of FIG. 12B is equivalent to the cross-sectional view corresponding to FIG. 9 of the semiconductor device of Embodiment 2 shown in FIGS. 8A, 8B and 9 except that the top semiconductor layer 205 is replaced with a buried semiconductor layer 217 described below. Also, a part of composing elements is omitted in FIG. 12B.

As shown in FIGS. 12A, 12B and 9, a resurf region 202 of, for example, N-type conductivity (with, for example, an impurity concentration of 2×10¹⁶/cm³ and a depth of 7 μm) is formed in a surface portion of a semiconductor substrate 201 of, for example, P⁻-type conductivity (with, for example, an impurity concentration of 1×10¹⁴/cm³). Furthermore, a base region 206 of, for example, P-type conductivity (with, for example, an impurity concentration of 1×10¹⁶/cm³ and a depth of 4 μm) is formed in a surface portion of the semiconductor substrate 201 to be adjacent to the resurf region 202.

In the base region 206, a contact region 210 of, for example, P⁺-type conductivity (with, for example, an impurity concentration of 1×10¹⁹/cm³ and a depth of 2 μm) and an emitter/source region 208 of, for example, N⁺-type conductivity (with, for example, an impurity concentration of 1×10²⁰/cm³ and a depth of 0.5 μm) are formed to be spaced from the resurf region 202. Also, a gate insulating film 203 is formed so as to cover a portion of the base region 206 disposed between the emitter/source region 208 and the resurf region 202, and a gate electrode 207 is formed on the gate insulating film 203.

When the gate insulating film 203 is formed to extend over the emitter/source region 208, a short circuit between the gate electrode 207 and the emitter/source region 208 can be prevented.

Furthermore, a buried semiconductor layer 217 of, for example, P-type conductivity (with, for example, an impurity concentration of 2×10¹⁶/cm³) is formed in the resurf region 202. The buried semiconductor layer 217 is formed at a depth of, for example, approximately 1 μm (corresponding to a depth Z of FIG. 12A) from the top face of the substrate 201 in a width along the depth direction of, for example, approximately 1 μm (corresponding to a width W of FIG. 12A). Although not shown in the drawing, the buried semiconductor layer 217 is electrically connected to the base region 206 through a given portion of the resurf region 202, an upper layer interconnect or the like.

Furthermore, a collector region 218 of, for example, P-type conductivity (with, for example, an impurity concentration of 2×10¹⁶/cm³) is formed in the resurf region 202 to be spaced from the buried semiconductor layer 217. At this point, the collector region 218 has substantially the same impurity concentration as and is disposed at substantially the same depth as the buried semiconductor layer 217. Moreover, a collector contact region 219 of, for example, P⁺-type conductivity (with, for example, an impurity concentration of 1×10¹⁹/cm³ and a depth of 1 μm) is formed in a surface portion of the resurf region 202 to be in contact with the collector region 218.

Furthermore, a drain region 216 of, for example, N⁺-type conductivity (with, for example, an impurity concentration of 1×10²⁰/cm³ and a depth of 0.5 μm) is formed in a surface portion of the resurf region 202 to be spaced from the buried semiconductor layer 217.

At this point, each of the collector region 218 and the drain region 216 includes a plurality of sections separated from one another as shown in FIG. 12B. Also, the sections of the collector region 218 and the sections of the drain region 216 are alternately arranged along a direction vertical to a direction extending from the collector region 218 toward the emitter/source region 208 (hereinafter sometimes simply referred to as the vertical direction). The length of each section of the collector region 215 along the vertical direction (corresponding to a length X of FIG. 12B) is, for example, approximately 60 μm, and the length of each section of the drain region 216 along the vertical direction (corresponding to a length Y of FIG. 12B) is, for example, approximately 30 μm.

An interlayer film 211 is formed above the semiconductor substrate 201 having the aforementioned various impurity regions or the like with a field insulating film 204 formed between the semiconductor substrate 201 including the resurf region 202 and the interlayer film 211.

Above the semiconductor substrate 201, a collector/drain electrode 212 penetrating the interlayer film 211 and electrically connected to both the collector contact region 219 (i.e., the collector region 218) and the drain region 216 is formed, and an emitter/source electrode 213 penetrating the interlayer film 211 and electrically connected to both the contact region 210 (i.e., the base region 206) and the emitter/source region 208 is formed.

A protective film 214 is formed on the interlayer film 211 on which the collector/drain electrode 212 and the emitter/source electrode 213 are formed.

In the semiconductor device of this embodiment, in the case where a positive voltage is applied to the gate electrode 207 with positive bias (hereinafter sometimes referred to as the collector voltage) applied between the collector/drain electrode 212 and the emitter/source electrode 213, an electron current (hereinafter sometimes referred to as the collector current) flows from the drain region 216 toward the emitter/source electrode 213, and thus, a MOSFET operation is performed. Furthermore, when the electron current, namely, the collector current, flowing toward the emitter/source electrode 213 is increased to some extent and a potential difference caused between the potential of the collector region 218 and the potential of a portion of the resurf region 202 surrounding the collector region 218 becomes approximately 0.6 V, holes are injected from the collector region 218 to the resurf region 202, and thus, the MOSFET operation is changed to an IGBT operation.

In this manner, in the semiconductor device of this embodiment, the MOSFET operation can be performed when the collector current flowing in the device is comparatively small, and the IGBT operation can be performed when the collector current flowing in the device is increased to some extent. In other words, a semiconductor device capable of performing the MOSFET operation or the IGBT operation in accordance with the amount of collector current flowing in the device can be realized. Furthermore, in the semiconductor device of this embodiment, the impurity concentration in the collector region 218 is set to be as low as the impurity concentration in the buried semiconductor layer 217, and hence, as compared with the case where the collector region is made of a high concentration layer (a P⁺-type layer) (as in the comparative example), the amount of excessive carriers injected into the semiconductor substrate 201 including the resurf region 202 during the IGBT operation can be suppressed. As a result, the amount of excessive carriers remaining in the semiconductor substrate 201 in turn off can be reduced so as to shorten the time necessary for drawing the carriers. Therefore, the switching speed can be improved, so as to reduce the switching loss. In other words, a high-breakdown voltage semiconductor device in which the loss is reduced in the whole region ranging from light load to heavy load can be realized.

Furthermore, in the semiconductor device (the switching device) of this embodiment in particular, the buried semiconductor layer 217 is formed in the resurf region 202, and therefore, a depletion layer can be formed to extend from the buried semiconductor layer to both the upward and downward directions. Accordingly, as compared with the case where the top semiconductor layer 205 is formed (as in Embodiment 2), the impurity concentration in the resurf region 202 can be made higher, so as to improve the switching speed and reduce the on resistance.

Also, in the comparative example in which the collector region is made of the high concentration layer (the P⁺-type semiconductor layer), it is necessary to provide an N-type buffer layer with a higher impurity concentration than the resurf region between the collector region and the resurf region for reducing the efficiency for injecting holes from the collector region to the resurf region. On the contrary, since the collector region 218 is formed to have a low concentration in the semiconductor device of this embodiment, there is no need to provide such an N-type buffer layer, which can simplify the fabrication process. Furthermore, the problem of the comparative example that it is difficult to change the MOSFET operation to the IGBT operation because of the N-type buffer layer can be avoided.

In this embodiment, the structure including the drain region 216, namely, the structure in which the MOSFET operation is changed to the IGBT operation, is described. As described in Embodiment 1, also in a structure not including the drain region 216, namely, a structure of a lateral type IGBT, the same effect as that of this embodiment, that is, the effect to reduce the loss in the whole region ranging from light load to heavy load, can be attained.

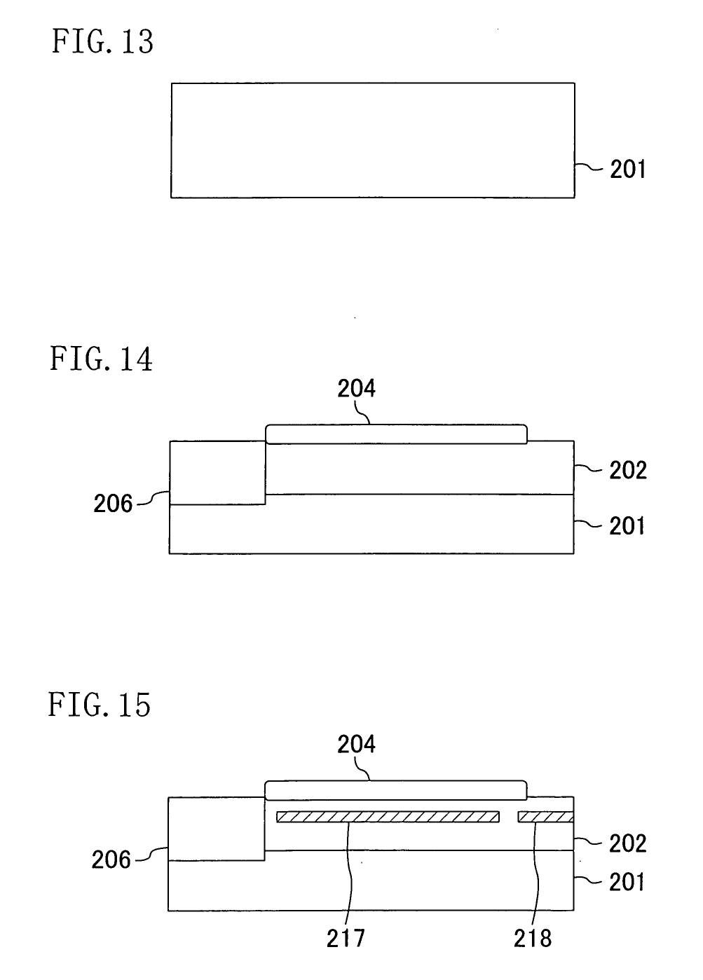

Now, an exemplified method for fabricating the switching device of this embodiment shown in FIGS. 12A, 12B and 9 will be described with reference to cross-sectional views of FIGS. 13 through 18.

First, in a procedure shown in FIG. 13, a P⁻-type semiconductor substrate 201 with, for example, an impurity concentration of approximately 1×10¹⁴/cm³ is prepared.

Next, in a procedure shown in FIG. 14, a resurf region 202 of, for example, N-type conductivity is selectively formed in a surface portion of the semiconductor substrate 201 by, for example, phosphorous ion implantation. The impurity concentration in the resurf region 202 is, for example, approximately 2×10¹⁶/cm³ and the depth of the resurf region 202 is, for example, approximately 7 μm. Thereafter, a base region 206 of, for example, P-type conductivity is formed in a surface portion of the semiconductor substrate 201 by, for example, boron ion implantation. The base region 206 is formed to be adjacent to the resurf region 202. The impurity concentration in the base region 206 is, for example, approximately 1×10¹⁶/cm³ and the depth of the base region 206 is, for example, 4 μm. Furthermore, a field insulating film 204 with a thickness of, for example, 500 nm is selectively formed on the resurf region 202 by, for example, wet oxidation or the like.

Next, in a procedure shown in FIG. 15, a buried semiconductor layer 217 of, for example, P-type conductivity and a collector region 218 of, for example, P-type conductivity are simultaneously and selectively formed in the resurf region 202 by, for example, high-energy boron ion implantation. At this point, the buried semiconductor layer 217 and the collector region 218 are formed to be spaced from each other. Also, the impurity concentration in the buried semiconductor layer 217 and the collector region 218 is, for example, approximately 2×10¹⁶/cm³. Furthermore, the buried semiconductor layer 217 and the collector region 218 are formed at a depth of, for example, approximately 1 μm (corresponding to a depth Z of FIG. 12A) from the top face of the substrate 201 in a width along the depth direction of, for example, approximately 1 μm (corresponding to a width W of FIG. 12A). Since the buried semiconductor layer 217 is formed by the ion implantation performed through the field insulating film 204, the depth of the collector region 218 is slightly larger than the depth of the buried semiconductor layer 217.

Although not shown in the drawing, the buried semiconductor layer 217 is electrically connected to the base region 206.

It is noted that the order of performing ion implantation for forming the respective impurity regions of this embodiment is not particularly specified.

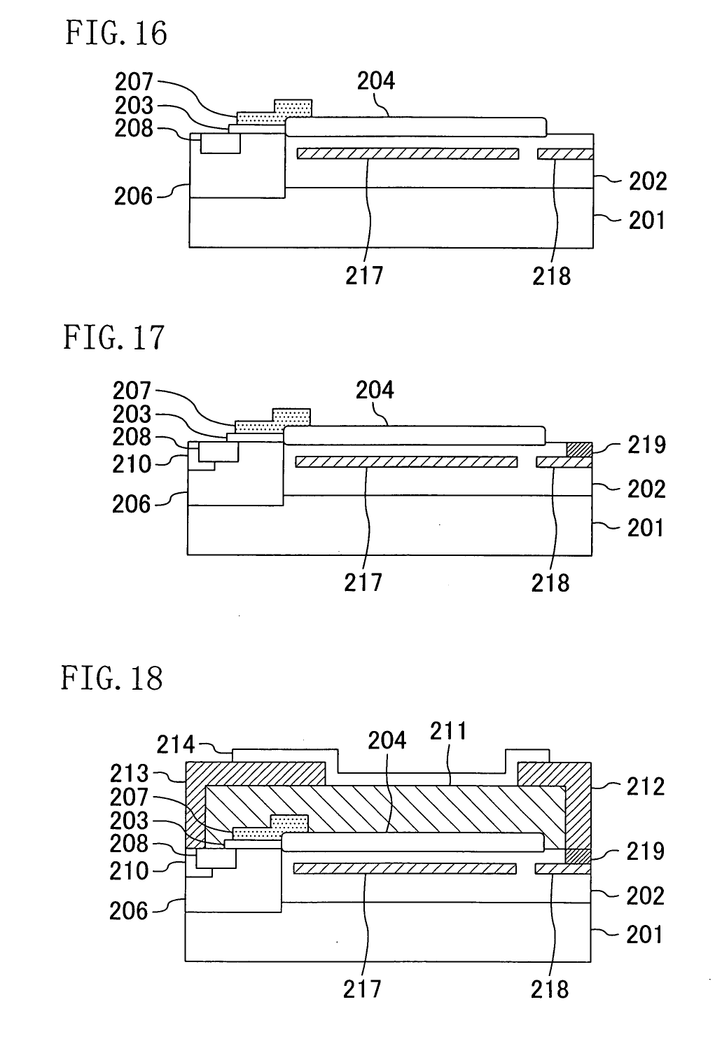

Next, in a procedure shown in FIG. 16, a gate insulating film 203 is formed by, for example, thermal oxidation so as to cover a portion of the base region 206 disposed between an emitter/source region 208 described below and the resurf region 202. Thereafter, a gate electrode 207 made of, for example, polysilicon is selectively formed on the gate insulating film 203. Furthermore, the emitter/source region 208 of, for example, N⁺-type conductivity is selectively formed in the base region 206 in a self-alignment manner by, for example, arsenic ion implantation with the gate electrode 207 and a resist pattern not shown used as a mask. Simultaneously, a drain region 216 of, for example, N⁺-type conductivity is selectively formed in a self-alignment manner in the resurf region 202 (as shown in FIGS. 12B and 9). The emitter/source region 208 is spaced from the resurf region 202, and the drain region 216 is spaced from the buried semiconductor layer 217. The impurity concentration in the emitter/source region 208 and the drain region 216 is, for example, approximately 1×10²⁰/cm³, and the depth of the emitter/source region 208 and the drain region 216 is, for example, approximately 0.5 μm.

Then, in a procedure shown in FIG. 17, a contact region 210 of, for example, P⁺-type conductivity is formed by, for example, boron ion implantation in the base region 206. The contact region 210 is spaced from the resurf region 202. The impurity concentration in the contact region 210 is, for example, approximately 1×10⁹/cm³, and the depth of the contact region 210 is, for example, 2 μm. Thereafter, a collector contact region 219 of, for example, P⁺-type conductivity is formed by, for example, boron ion implantation, in a surface portion of the resurf region 202 to be in contact with the collector region 218. The impurity concentration in the collector contact region 219 is, for example, approximately 1×10¹⁹/cm³, and the depth of the collector contact region 219 is, for example, 1 μm.

Next, in a procedure shown in FIG. 18, an interlayer film 211 is formed by, for example, atmospheric pressure CVD above the semiconductor substrate 201 including regions on the field insulating film 204 and the gate electrode 207. Thereafter, an opening is formed in a given portion of the interlayer film 211, so as to form, above the semiconductor substrate 201, a collector/drain electrode 212 electrically connected to both the collector contact region 219 (i.e., the collector region 218) and the drain region 216 and an emitter/source electrode 213 electrically connected to both the contact region 210 (i.e., the base region 206) and the emitter/source region 208. Ultimately, after forming a protective film 214 made of, for example, a plasma SiN film on the interlayer film 211, an opening is formed in a pad forming region of the protective film 214. In this manner, the switching device of this embodiment shown in FIGS. 12A, 12B and 9 is completed.

In the aforementioned fabrication method of this embodiment, since the buried semiconductor layer 217 and the collector region 218 are formed in one and the same impurity implantation process, the number of procedures can be reduced and the cost can be lowered as compared with the case they are individually formed.

### Embodiment 4

A semiconductor device according to Embodiment 4 of the invention, that is, a high-breakdown voltage semiconductor switching device specifically, will now be described with reference to the accompanying drawings.

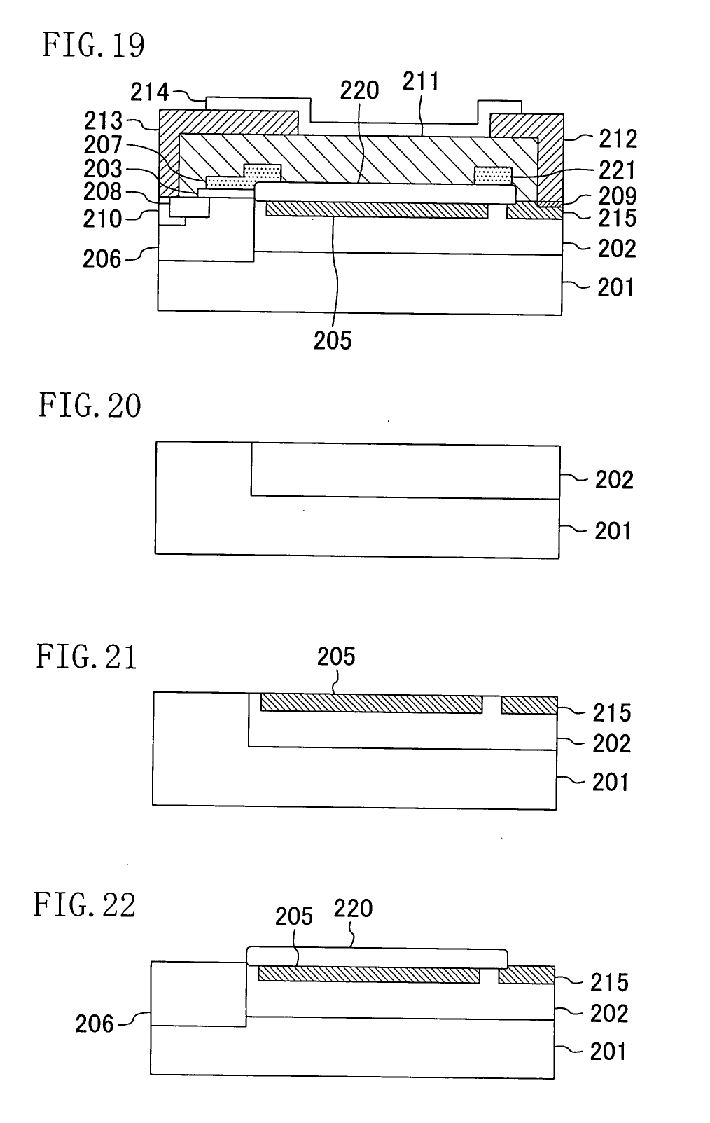

FIG. 19 is a cross-sectional view of the semiconductor device of Embodiment 4. As shown in FIG. 19, a resurf region 202 of, for example, N-type conductivity (with, for example, an impurity concentration of 1×10¹⁶/cm³ and a depth of 7 μm) is formed in a surface portion of a semiconductor substrate 201 of, for example, P⁻-type conductivity (with, for example, an impurity concentration of 1×10¹⁴/cm³). Furthermore, a base region 206 of, for example, P-type conductivity (with, for example, an impurity concentration of 1×10¹⁶/cm³ and a depth of 4 μm) is formed in a surface portion of the semiconductor substrate 201 to be adjacent to the resurf region 202.

In the base region 206, a contact region 210 of, for example, P⁺-type conductivity (with, for example, an impurity concentration of 1×10¹⁹/cm³ and a depth of 2 μm) and an emitter region 208 of, for example, N⁺-type conductivity (with, for example, an impurity concentration of 1×10²⁰/cm³ and a depth of 0.5 μm) are formed to be spaced from the resurf region 202. Also, a first gate insulating film 203 is formed so as to cover a portion of the base region 206 disposed between the emitter region 208 and the resurf region 202, and a first gate electrode 207 is formed on the first gate insulating film 203.

When the first gate insulating film 203 is formed to extend over the emitter region 208, a short circuit between the first gate electrode 207 and the emitter region 208 can be prevented.

Furthermore, a top semiconductor layer 205 of, for example, P-type conductivity (with, for example, an impurity concentration of 1×10¹⁶/cm³ and a depth of 1 μm) is formed in a surface portion of the resurf region 202. Although not shown in the drawing, the top semiconductor layer 205 is electrically connected to the base region 206 through a given portion of the resurf region 202, an upper layer interconnect or the like.

Also, a collector region 215 of, for example, P-type conductivity (with, for example, an impurity concentration of 1×10¹⁶/cm³ and a depth of 1 μm) is formed in a surface portion of the resurf region 202 to be spaced from the top semiconductor layer 205. At this point, the collector region 215 has substantially the same impurity concentration as and is disposed at substantially the same depth as the top semiconductor layer 205.

A collector contact region 209 of, for example, P⁺-type conductivity (with, for example, an impurity concentration of 1×10¹⁹/cm³ and a depth of 0.5 μm) is formed in a surface portion of the collector region 215. It is noted that the collector contact region 209 can be omitted.

Furthermore, a second gate insulating film 220 is formed on the resurf region 202 so as to extend from a portion on the collector region 215 to a portion on the top semiconductor layer 205. Also, a second gate electrode 221 is formed on a portion of the second gate insulating film 220 disposed between the collector region 215 and the top semiconductor layer 205. Although not shown in the drawing, the second gate electrode 221 is electrically connected to the first gate electrode 207 through a gate electrode interconnect, an upper layer interconnect or the like.

An interlayer film 211 is formed above the semiconductor substrate 201 having the aforementioned various impurity regions, gate electrodes and the like.

Above the semiconductor substrate 201, a collector electrode 212 penetrating the interlayer film 211 and electrically connected to the collector contact region 209 (i.e., the collector region 215) is formed, and an emitter electrode 213 penetrating the interlayer film 211 and electrically connected to both the contact region 210 (i.e., the base region 206) and the emitter region 208 is formed.

A protective film 214 is formed on the interlayer film 211 on which the collector electrode 212 and the emitter electrode 213 are formed.

In the semiconductor device of this embodiment, in the case where a positive voltage is applied to the first gate electrode 207 with positive bias applied between the collector electrode 212 and the emitter electrode 213 (with a side of the collector electrode 212 set to high potential), when a potential difference caused between the potential of the collector region 215 and the potential of a portion of the resurf region 202 surrounding the collector region 215 becomes approximately 0.6 V, holes are injected from the collector region 215 to the resurf region 202, and thus, an IGBT operation is started. Specifically, the semiconductor device (the switching device) of this embodiment is a lateral type IGBT.

In the semiconductor device (the switching device) of this embodiment, at the time of turn off of the switching device (namely, when the voltages of the first gate electrode 207 and the second gate electrode 221 are both lowered from, for example, 6 V to 0 V assuming that the voltage of the emitter electrode 213 is 0 V), the potential of a portion of the resurf region 202 disposed between the collector region 215 and the top semiconductor layer 205 (hereinafter sometimes referred to as the collector potential) is also increased, and hence, a P-channel MOSFET formed by using a part of the collector region 215 is turned on. Thus, excessive carriers remaining in the resurf region 202 can be drawn through a path extending from the collector region 215 and passing through the P-channel MOSFET, the top semiconductor layer 205, the base region 206 and the contact region 210. In addition, the excessive carriers remaining in the resurf region 202 can be drawn also through the top semiconductor layer 205. Therefore, the fall time tf can be shortened, namely, the switching speed can be improved by reducing the time required for drawing the carriers, and hence, the switching loss can be reduced.

In this embodiment, the excessive carriers (holes) remaining in the resurf region 202 are drawn by increasing the collector potential in turn off, and thereafter, a hole current passing through the path including the P-channel MOSFET from the collector electrode 212 can be stopped since a depletion layer extends from the top semiconductor layer 205 in the resurf region 202. Accordingly, the breakdown voltage characteristic of the device is never degraded.

Also, in the semiconductor device of this embodiment, the impurity concentration in the collector region 215 is set to be as low as the impurity concentration in the top semiconductor layer 205, and hence, as compared with the case where the collector region is made of a high concentration layer (a P⁺-type layer), the amount of excessive carriers injected into the semiconductor substrate 201 including the resurf region 202 during the IGBT operation can be suppressed. As a result, since the amount of excessive carriers remaining in the semiconductor substrate 201 in turn off can be reduced, the time necessary for drawing the carriers can be shortened. Therefore, the switching speed can be improved, so as to reduce the switching loss. Specifically, a high-breakdown voltage semiconductor device in which the loss can be reduced in the whole region ranging from light load to heavy load can be realized.

Moreover, in the case where the collector region is made of a high concentration layer, it is necessary to provide a buffer layer of, for example, N-type conductivity with a higher impurity concentration than the resurf region between the collector region and the resurf region for reducing the efficiency for injecting holes from the collector region to the resurf region. On the contrary, since the collector region 215 is formed to have a low concentration in the semiconductor device of this embodiment, there is no need to provide such an N-type buffer layer, and hence, the fabrication process can be simplified.

Although a structure in which a drain region is not formed, namely, a structure in which a MOSFET operation is not changed to an IGBT operation, is described in this embodiment, the same effect as that of this embodiment, namely, the effect to reduce the loss in the whole region ranging from light load to heavy load, can be attained also when a drain region is provided as described in Embodiment 2 or 3. Also in this case, each of the collector region 215 and the drain region may include a plurality of sections separated from one another, and the sections of the collector region 215 and the sections of the drain region may be alternately arranged along a direction vertical to a direction extending from the collector region 215 toward the emitter region 208 (the emitter/source region in this case).

Now, an exemplified method for fabricating the switching device of this embodiment shown in FIG. 19 will be described with reference to cross-sectional views of FIGS. 20 through 25.

First, in a procedure shown in FIG. 20, a resurf region 202 of, for example, N-type conductivity is selectively formed in a surface portion of a semiconductor substrate 201 of, for example, P⁻-type conductivity with an impurity concentration of, for example, approximately 1×10¹⁴/cm³ by, for example, phosphorous ion implantation. The impurity concentration in the resurf region 202 is, for example, approximately 1×10¹⁶/cm³ and the depth of the resurf region 202 is, for example, approximately 7 μm.

Next, in a procedure shown in FIG. 21, a top semiconductor layer 205 of, for example, P-type conductivity and a collector region 215 of, for example, P-type conductivity are simultaneously and selectively formed by, for example, boron ion implantation in surface portions of the resurf region 202. At this point, the top semiconductor layer 205 and the collector region 215 are spaced from each other. Also, the impurity concentration in the top semiconductor layer 205 and the collector region 215 is, for example, approximately 1×10¹⁶/cm³, and the depth of the top semiconductor layer 205 and the collector region 215 is, for example, approximately 1 μm.

It is noted that the top semiconductor layer 205 is electrically connected to a base region 206 described below although not shown in the drawing.

Then, in a procedure shown in FIG. 22, the base region 206 of, for example, P-type conductivity is formed by, for example, boron ion implantation in a surface portion of the semiconductor substrate 201. The base region 206 is formed to be adjacent to the resurf region 202. The impurity concentration in the base region 206 is, for example, 1×10¹⁶/cm³, and the depth of the base region 206 is, for example, 4 μm. Furthermore, a second insulating film 220 with a thickness of, for example, 500 nm is selectively formed above the resurf region 202 by, for example, wet oxidation or the like so as to extend from a portion on the collector region 215 to a portion on the top semiconductor layer 205. At this point, the impurity of the top semiconductor layer 205 is diffused so that its impurity concentration can be slightly lowered.

It is noted that the order of performing ion implantation for forming the respective impurity regions of this embodiment is not particularly specified.

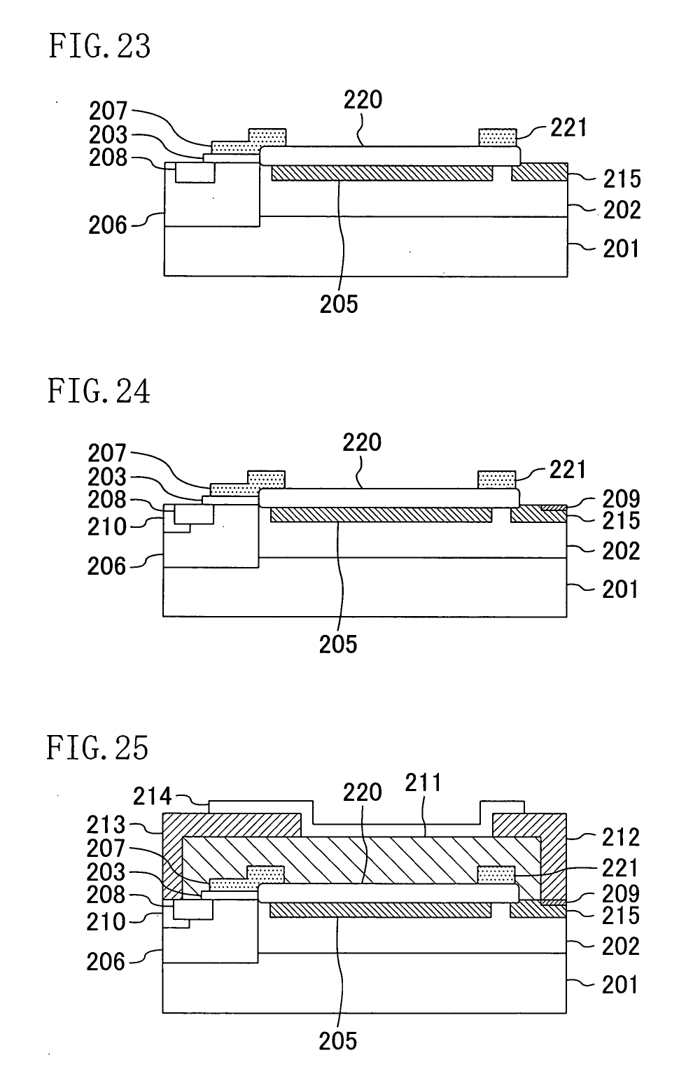

Next, in a procedure shown in FIG. 23, a first gate insulating film 203 is formed by, for example, thermal oxidation so as to cover a portion of the base region 206 disposed between an emitter region 208 described below and the resurf region 202. Thereafter, a first gate electrode 207 made of, for example, polysilicon is selectively formed on the first gate insulating film 203. Simultaneously, a second gate electrode 221 made of, for example, polysilicon is selectively formed on a portion of the second gate insulating film 220 disposed between the collector region 215 and the top semiconductor layer 205. Furthermore, the emitter region 208 of, for example, N⁺-type conductivity is selectively formed in the base region 206 in a self-alignment manner by, for example, arsenic ion implantation with the first gate electrode 207 used as a mask. The emitter region 208 is spaced from the resurf region 202. The impurity concentration in the emitter region 208 is, for example, approximately 1×10²⁰/cm³, and the depth of the emitter region 208 is, for example, approximately 0.5 μm.

Then, in a procedure shown in FIG. 24, a contact region 210 of, for example, P⁺-type conductivity is formed by, for example, boron ion implantation in the base region 206. The contact region 210 is spaced from the resurf region 202. The impurity concentration in the contact region 210 is, for example, approximately 1×10¹⁹/cm³, and the depth of the contact region 210 is, for example, 2 μm. Thereafter, a collector contact region 209 of, for example, P⁺-type conductivity is formed by, for example, boron ion implantation, in a surface portion of the collector region 215. The impurity concentration in the collector contact region 209 is, for example, approximately 1×10¹⁹/cm³, and the depth of the collector contact region 209 is, for example, 0.5 μm. It is noted that the collector contact region 209 may be omitted.

Next, in a procedure shown in FIG. 25, an interlayer film 211 is formed by, for example, atmospheric pressure CVD above the semiconductor substrate 201 including the respective impurity regions, the gate electrodes and the like. Thereafter, an opening is formed in a given portion of the interlayer film 211, so as to form, above the semiconductor substrate 201, a collector electrode 212 electrically connected to the collector contact region 209 (i.e., the collector region 215) and an emitter electrode 213 electrically connected to both the contact region 210 (i.e., the base region 206) and the emitter region 208. Ultimately, after forming a protective film 214 made of, for example, a plasma SiN film on the interlayer film 211, an opening is formed in a pad forming region of the protective film 214. In this manner, the switching device of this embodiment shown in FIG. 19 is completed.

In the fabrication method of this embodiment described above, the top semiconductor layer 205 and the collector region 215 are formed in one and the same impurity implantation process, and therefore, the number of procedures can be reduced and the cost can be lowered as compared with the case where they are individually formed.

### Embodiment 5

A semiconductor device according to Embodiment 5 of the invention, that is, a high-breakdown voltage semiconductor switching device specifically, will now be described with reference to the accompanying drawings.

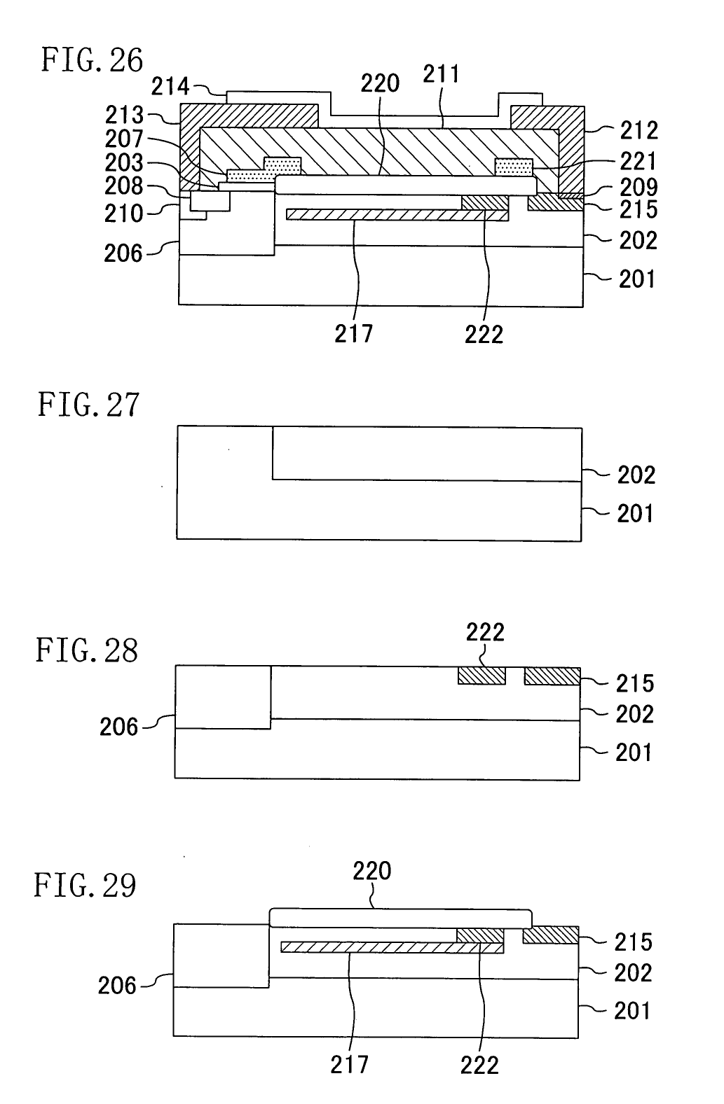

FIG. 26 is a cross-sectional view of the semiconductor device of Embodiment 5. As shown in FIG. 26, a resurf region 202 of, for example, N-type conductivity (with, for example, an impurity concentration of 2×10¹⁶/cm³ and a depth of 7 μm) is formed in a surface portion of a semiconductor substrate 201 of, for example, P⁻-type conductivity (with, for example, an impurity concentration of 1×10¹⁴/cm³). Furthermore, a base region 206 of, for example, P-type conductivity (with, for example, an impurity concentration of 1×10¹⁶/cm³ and a depth of 4 μm) is formed in a surface portion of the semiconductor substrate 201 to be adjacent to the resurf region 202.

In the base region 206, a contact region 210 of, for example, P⁺-type conductivity (with, for example, an impurity concentration of 1×10¹⁹/cm³ and a depth of 2 μm) and an emitter region 208 of, for example, N⁺-type conductivity (with, for example, an impurity concentration of 1×10²⁰/cm³ and a depth of 0.5 μm) are formed to be spaced from the resurf region 202. Also, a first gate insulating film 203 is formed so as to cover a portion of the base region 206 disposed between the emitter region 208 and the resurf region 202, and a first gate electrode 207 is formed on the first gate insulating film 203.

When the first gate insulating film 203 is formed to extend over the emitter region 208, a short circuit between the first gate electrode 207 and the emitter region 208 can be prevented.

Furthermore, a top semiconductor layer 222 of, for example, P-type conductivity (with, for example, an impurity concentration of 1×10¹⁶/cm³ and a depth of 1 μm) is formed in a surface portion of the resurf region 202.

Also, a buried semiconductor layer 217 of, for example, P-type conductivity (with, for example, an impurity concentration of 2×10¹⁶/cm³) is formed in the resurf region 202 beneath the top semiconductor layer 222 so as to be in contact with the top semiconductor layer 222. The buried semiconductor layer 217 is formed at a depth of, for example, approximately 1 μm from the top face of the substrate 201 in a width along the depth direction of, for example, approximately 1 μm. Although not shown in the drawing, the buried semiconductor layer 217 is electrically connected to the base region 206 through a given portion of the resurf region 202, an upper layer interconnect or the like. In other words, the top semiconductor layer 222 and the base region 206 are electrically connected to each other through the buried semiconductor layer 217.

Furthermore, a collector region 215 of, for example, P-type conductivity (with, for example, an impurity concentration of 1×10¹⁶/cm³ and a depth of 1 μm) is formed in a surface portion of the resurf region 202 to be spaced from the top semiconductor layer 222. At this point, the collector region 215 has substantially the same impurity concentration as and is disposed at substantially the same depth as the top semiconductor layer 222.

While the buried semiconductor layer 217 is formed in the resurf region 202 so as to extend from the vicinity of the collector region 215 to the vicinity of the base region 206, the top semiconductor layer 222 is formed in the resurf region 202 merely in the vicinity of the collector region 215. Also, the top semiconductor layer 222 includes a plurality of sections separated from one another arranged in a direction vertical to a direction extending from the collector region 215 toward the base region 206. This is for securing a path for drawing carriers described below.

A collector contact region 209 of, for example, P⁺-type conductivity (with, for example, an impurity concentration of 1×10¹⁹/cm³ and a depth of 0.5 μm) is formed in a surface portion of the collector region 215. It is noted that the collector contact region 209 can be omitted.

Furthermore, a second gate insulating film 220 is formed above the resurf region 202 so as to extend from a portion on the collector region 215 at least to a portion on the top semiconductor layer 222. Also, a second gate electrode 221 is formed on a portion of the second gate insulating film 220 disposed between the collector region 215 and the top semiconductor layer 222. Although not shown in the drawing, the second gate electrode 221 is electrically connected to the first gate electrode 207 through a gate electrode interconnect, an upper layer interconnect or the like.

An interlayer film 211 is formed above the semiconductor substrate 201 having the aforementioned various impurity regions, gate electrodes and the like.

Above the semiconductor substrate 201, a collector electrode 212 penetrating the interlayer film 211 and electrically connected to the collector contact region 209 (i.e., the collector region 215) is formed, and an emitter electrode 213 penetrating the interlayer film 211 and electrically connected to both the contact region 210 (i.e., the base region 206) and the emitter region 208 is formed.

A protective film 214 is formed on the interlayer film 211 on which the collector electrode 212 and the emitter electrode 213 are formed.

The operation of the semiconductor device of this embodiment is basically the same as that of Embodiment 4. Specifically, in the case where a positive voltage is applied to the first gate electrode 207 with positive bias applied between the collector electrode 212 and the emitter electrode 213 (with a side of the collector electrode 212 set to high potential), when a potential difference caused between the potential of the collector region 215 and the potential of a portion of the resurf region 202 surrounding the collector region 215 becomes approximately 0.6 V, holes are injected from the collector region 215 to the resurf region 202, and thus, an IGBT operation is started. Specifically, the semiconductor device (the switching device) of this embodiment is a lateral type IGBT.

In the semiconductor device (the switching device) of this embodiment, at the time of turn off of the switching device (namely, when the voltages of the first gate electrode 207 and the second gate electrode 221 are both lowered from, for example, 6 V to 0 V assuming that the voltage of the emitter electrode 213 is 0 V), the potential of a portion of the resurf region 202 disposed between the collector region 215 and the top semiconductor layer 222 (hereinafter sometimes referred to as the collector potential) is also increased, and hence, a P-channel MOSFET formed by using a part of the collector region 215 is turned on. Thus, excessive carriers remaining in the resurf region 202 can be drawn through a path extending from the collector region 215 and passing through the P-channel MOSFET, the top semiconductor layer 222, the buried semiconductor layer 217, the base region 206 and the contact region 210. In addition, the excessive carriers remaining in the resurf region 202 can be drawn also through the top semiconductor layer 222 and the buried semiconductor layer 217. Therefore, the fall time tf can be shortened, namely, the switching speed can be improved by reducing the time required for drawing the carriers, and hence, the switching loss can be reduced.

In this embodiment, the excessive carriers (holes) remaining in the resurf region 202 are drawn by increasing the collector potential in turn off, and thereafter, a hole current passing through the path including the P-channel MOSFET from the collector electrode 212 can be stopped since a depletion layer extends from the top semiconductor layer 222 and the buried semiconductor layer 217 in the resurf region 202. Accordingly, the breakdown voltage characteristic of the device is never degraded.

Also, in the semiconductor device of this embodiment, the impurity concentration in the collector region 215 is set to be as low as the impurity concentration in the top semiconductor layer 222, and hence, as compared with the case where the collector region is made of a high concentration layer (a P⁺-type layer), the amount of excessive carriers injected into the semiconductor substrate 201 including the resurf region 202 during the IGBT operation can be suppressed. As a result, since the amount of excessive carriers remaining in the semiconductor substrate 201 in turn off can be reduced, the time necessary for drawing the carriers can be shortened. Therefore, the switching speed can be improved, so as to reduce the switching loss. Specifically, a high-breakdown voltage semiconductor device in which the loss can be reduced in the whole region ranging from light load to heavy load can be realized.

Moreover, in the case where the collector region is made of a high concentration layer, it is necessary to provide a buffer layer of, for example, N-type conductivity with a higher impurity concentration than the resurf region between the collector region and the resurf region for reducing the efficiency for injecting holes from the collector region to the resurf region. On the contrary, since the collector region 215 is formed to have a low concentration in the semiconductor device of this embodiment, there is no need to provide such an N-type buffer layer, and hence, the fabrication process can be simplified.

Furthermore, since the buried semiconductor layer 217 is additionally formed in the resurf region 202 in the semiconductor device of this embodiment, a depletion layer can be formed to extend in both the upward and downward directions from the buried semiconductor layer 217 as compared with the case where the top semiconductor layer 205 alone is formed in the resurf region 202 (as in Embodiment 4). Therefore, the impurity concentration in the resurf region 202 can be further increased, so as to improve the switching speed and reduce the on resistance.

Although a structure in which a drain region is not formed, namely, a structure in which a MOSFET operation is not changed to an IGBT operation, is described in this embodiment, the same effect as that of this embodiment, namely, the effect to reduce the loss in the whole region ranging from light load to heavy load, can be attained also when a drain region is provided as described in Embodiment 2 or 3. Also in this case, each of the collector region 215 and the drain region may include a plurality of sections separated from one another, and the sections of the collector region 215 and the sections of the drain region may be alternately arranged along a direction vertical to a direction extending from the collector region 215 toward the emitter region 208 (the emitter/source region in this case).

Now, an exemplified method for fabricating the switching device of this embodiment shown in FIG. 26 will be described with reference to cross-sectional views of FIGS. 27 through 32.

First, in a procedure shown in FIG. 27, a resurf region 202 of, for example, N-type conductivity is selectively formed in a surface portion of a semiconductor substrate 201 of, for example, P⁻-type conductivity with an impurity concentration of, for example, approximately 1×10¹⁴/cm³ by, for example, phosphorous ion implantation. The impurity concentration in the resurf region 202 is, for example, approximately 2×10¹⁶/cm³ and the depth of the resurf region 202 is, for example, approximately 7 μm.

Next, in a procedure shown in FIG. 28, a top semiconductor layer 222 of, for example, P-type conductivity and a collector region 215 of, for example, P-type conductivity are simultaneously and selectively formed by, for example, boron ion implantation in surface portions of the resurf region 202. At this point, the top semiconductor layer 222 and the collector region 215 are spaced from each other. Also, the impurity concentration in the top semiconductor layer 222 and the collector region 215 is, for example, approximately 1×10¹⁶/cm³, and the depth of the top semiconductor layer 222 and the collector region 215 is, for example, approximately 1 μm.

Then, in a procedure shown in FIG. 29, a base region 206 of, for example, P-type conductivity is formed by, for example, boron ion implantation in a surface portion of the semiconductor substrate 201. The base region 206 is formed to be adjacent to the resurf region 202. The impurity concentration in the base region 206 is, for example, 1×10¹⁶/cm³, and the depth of the base region 206 is, for example, 4 μm. Furthermore, a second insulating film 220 with a thickness of, for example, 500 nm is formed on the resurf region 202 by, for example, wet oxidation or the like so as to extend from a portion on the collector region 215 at least to a portion on the top semiconductor layer 222. At this point, the impurity of the top semiconductor layer 222 is diffused so that its impurity concentration can be slightly lowered.

Thereafter, a buried semiconductor layer 217 of, for example, P-type conductivity is selectively formed in the resurf region 202 beneath the top semiconductor layer 222 by, for example, high-energy boron ion implantation, so as to be in contact with the top semiconductor layer 222. The impurity concentration in the buried semiconductor layer 217 is, for example, approximately 2×10¹⁶/cm³. Also, the buried semiconductor layer 217 is formed at a depth of, for example, approximately 1 μm from the top face of the substrate 201 in a width along the depth direction of, for example, approximately 1 μm. Although not shown in the drawing, the buried semiconductor layer 217 is electrically connected to the base region 206.

It is noted that the order of performing ion implantation for forming the respective impurity regions of this embodiment is not particularly specified.

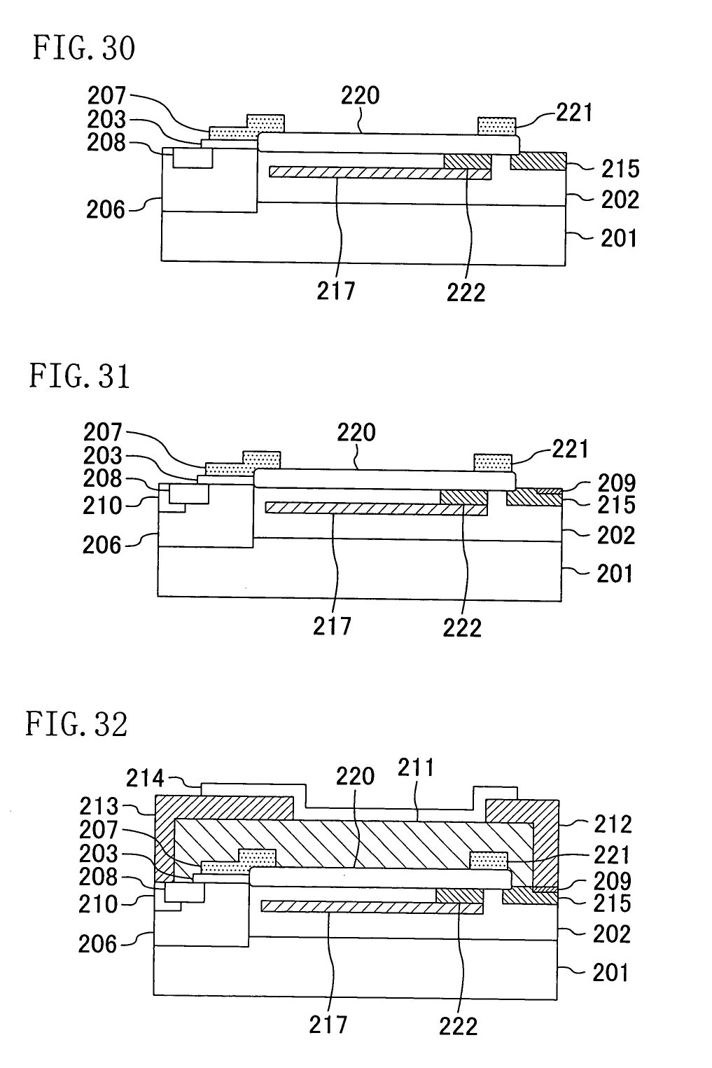

Next, in a procedure shown in FIG. 30, a first gate insulating film 203 is formed by, for example, thermal oxidation so as to cover a portion of the base region 206 disposed between an emitter region 208 described below and the resurf region 202. Thereafter, a first gate electrode 207 made of, for example, polysilicon is selectively formed on the first gate insulating film 203. Simultaneously, a second gate electrode 221 made of, for example, polysilicon is selectively formed on a portion of the second gate insulating film 220 disposed between the collector region 215 and the top semiconductor layer 222. Furthermore, an emitter region 208 of, for example, N⁺-type conductivity is selectively formed in the base region 206 in a self-alignment manner by, for example, arsenic ion implantation with the first gate electrode 207 used as a mask. The emitter region 208 is spaced from the resurf region 202. The impurity concentration in the emitter region 208 is, for example, approximately 1×10²⁰/cm³, and the depth of the emitter region 208 is, for example, approximately 0.5 μm.

Then, in a procedure shown in FIG. 31, a contact region 210 of, for example, P⁺-type conductivity is formed by, for example, boron ion implantation in the base region 206. The contact region 210 is spaced from the resurf region 202. The impurity concentration in the contact region 210 is, for example, approximately 1×10¹⁹/cm³, and the depth of the contact region 210 is, for example, 2 μm. Thereafter, a collector contact region 209 of, for example, P⁺-type conductivity is formed by, for example, boron ion implantation, in a surface portion of the collector region 215. The impurity concentration in the collector contact region 209 is, for example, approximately 1×10¹⁹/cm³, and the depth of the collector contact region 209 is, for example, 0.5 μm. It is noted that the collector contact region 209 may be omitted.

Next, in a procedure shown in FIG. 32, an interlayer film 211 is formed by, for example, atmospheric pressure CVD above the semiconductor substrate 201 including the various impurity regions, the gate electrodes and the like. Thereafter, an opening is formed in a given portion of the interlayer film 211, so as to form, above the semiconductor substrate 201, a collector electrode 212 electrically connected to the collector contact region 209 (i.e., the collector region 215) and an emitter electrode 213 electrically connected to both the contact region 210 (i.e., the base region 206) and the emitter region 208. Ultimately, after forming a protective film 214 made of, for example, a plasma SiN film on the interlayer film 211, an opening is formed in a pad forming region of the protective film 214. In this manner, the switching device of this embodiment shown in FIG. 26 is completed.

In the fabrication method of this embodiment described above, the top semiconductor layer 222 and the collector region 215 are formed in one and the same impurity implantation process, and therefore, the number of procedures can be reduced and the cost can be lowered as compared with the case where they are individually formed.

What is claimed is:

1. A semiconductor device comprising:
a resurf region of a second conductivity type formed in a surface portion of a semiconductor substrate of a first conductivity type;
a base region of the first conductivity type formed in said semiconductor substrate to be adjacent to said resurf region;
an emitter region of the second conductivity type formed in said base region to be spaced from said resurf region;
a first gate insulating film formed to cover a portion of said base region disposed between said emitter region and said resurf region;
a first gate electrode formed on said first gate insulating film;
a top semiconductor layer of the first conductivity type formed in a surface portion of said resurf region and electrically connected to said base region;
a collector region of the first conductivity type formed in a surface portion of said resurf region to be spaced from said top semiconductor layer, having substantially the same impurity concentration as said top semiconductor layer and disposed at substantially the same depth as said top semiconductor layer;
a collector electrode formed above said semiconductor substrate and electrically connected to said collector region; and
an emitter electrode formed above said semiconductor substrate and electrically connected to said base region and said emitter region.

2. A semiconductor device comprising:
a resurf region of a second conductivity type formed in a surface portion of a semiconductor substrate of a first conductivity type;
a base region of the first conductivity type formed in said semiconductor substrate to be adjacent to said resurf region;
an emitter/source region of the second conductivity type formed in said base region to be spaced from said resurf region;
a first gate insulating film formed to cover a portion of said base region disposed between said emitter/source region and said resurf region;
a first gate electrode formed on said first gate insulating film;
a top semiconductor layer of the first conductivity type formed in a surface portion of said resurf region and electrically connected to said base region;
a collector region of the first conductivity type formed in a surface portion of said resurf region to be spaced from said top semiconductor layer, having substantially the same impurity concentration as said top semiconductor layer and disposed at substantially the same depth as said top semiconductor layer;
a drain region of the second conductivity type formed in a surface portion of said resurf region to be spaced from said top semiconductor layer;
a collector/drain electrode formed above said semiconductor substrate and electrically connected to said collector region and said drain region; and
an emitter/source electrode formed above said semiconductor substrate and electrically connected to said base region and said emitter/source region.

3. The semiconductor device of claim 2,
wherein each of said collector region and said drain region includes a plurality of sections separated from one another, and
said sections of said collector region and said sections of said drain region are alternately arranged along a direction vertical to a direction extending from said collector region toward said emitter/source region.

4. The semiconductor device of claim 1, further comprising:
a second gate insulating film formed on said resurf region to extend from a portion on said collector region to a portion on said top semiconductor layer; and
a second gate electrode formed on said second gate insulating film.

5. The semiconductor device of claim 4, further comprising:
a buried semiconductor layer of the first conductivity type formed in said resurf region to be in contact with said top semiconductor layer and electrically connected to said base region.

6. The semiconductor device of claim 2, further comprising:
a second gate insulating film formed on said resurf region to extend from a portion on said collector region to a portion on said top semiconductor layer; and
a second gate electrode formed on said second gate insulating film.

7. The semiconductor device of claim 6, further comprising:
a buried semiconductor layer of the first conductivity type formed in said resurf region to be in contact with said top semiconductor layer and electrically connected to said base region.

8. A method for fabricating the semiconductor device of claim 1, comprising at least a step of forming said top semiconductor layer and said collector region through one impurity implantation process.

9. A method for fabricating the semiconductor device of claim 2, comprising at least a step of forming said top semiconductor layer and said collector region through one impurity implantation process.

10. A semiconductor device comprising:
a resurf region of a second conductivity type formed in a surface portion of a semiconductor substrate of a first conductivity type;
a base region of the first conductivity type formed in said semiconductor substrate to be adjacent to said resurf region;
an emitter region of the second conductivity type formed in said base region to be spaced from said resurf region;
a gate insulating film formed to cover a portion of said base region disposed between said emitter region and said resurf region;
a gate electrode formed on said gate insulating film;
a buried semiconductor layer of the first conductivity type formed in said resurf region and electrically connected to said base region;
a collector region of the first conductivity type formed in said resurf region to be spaced from said buried semiconductor layer, having substantially the same impurity concentration as said buried semiconductor layer and disposed at substantially the same depth as said buried semiconductor layer;
a collector contact region of the first conductivity type formed in a surface portion of said resurf region to be in contact with said collector region;
a collector electrode formed above said semiconductor substrate and electrically connected to said collector contact region; and
an emitter electrode formed above said semiconductor substrate and electrically connected to said base region and said emitter region.

11. A semiconductor device comprising:
a resurf region of a second conductivity type formed in a surface portion of a semiconductor substrate of a first conductivity type;
a base region of the first conductivity type formed in said semiconductor substrate to be adjacent to said resurf region;
an emitter/source region of the second conductivity type formed in said base region to be spaced from said resurf region;
a gate insulating film formed to cover a portion of said base region disposed between said emitter/source region and said resurf region;
a gate electrode formed on said gate insulating film;
a buried semiconductor layer of the first conductivity type formed in said resurf region and electrically connected to said base region;
a collector region of the first conductivity type formed in said resurf region to be spaced from said buried semiconductor layer, having substantially the same impurity concentration as said buried semiconductor layer and disposed at substantially the same depth as said buried semiconductor layer;
a collector contact region of the first conductivity type formed in a surface portion of said resurf region to be in contact with said collector region;
a drain region of the second conductivity type formed in a surface portion of said resurf region to be spaced from said buried semiconductor layer;
a collector/drain electrode formed above said semiconductor substrate and electrically connected to said collector contact region and said drain region; and
an emitter/source electrode formed above said semiconductor substrate and electrically connected to said base region and said emitter/source region.

12. The semiconductor device of claim 11,
wherein each of said collector region and said drain region includes a plurality of sections separated from one another, and
said sections of said collector region and said sections of said drain region are alternately arranged along a direction vertical to a direction extending from said collector region toward said emitter/source region.

13. A method for fabricating the semiconductor device of claim 10, comprising at least a step of forming said buried semiconductor layer and said collector region through one impurity implantation process.

14. A method for fabricating the semiconductor device of claim 11, comprising at least a step of forming said buried semiconductor layer and said collector region through one impurity implantation process.
